(19) United States
(12) Patent Application Publication
(10) Pub. No.: US 2026/0229482 A1
(43) Pub. Date: Aug. 6, 2026

(54) Apparatus for Uniform Deposition of Silicon in Pores of Porous Conductive Particles for Battery Anodes

(71) Applicant: Honeycomb Battery Company, Dayton, OH (US)

(72) Inventors: Hsun Lin, Dayton, OH (US); Sheng-Yi Lu, Taipei (TW); Yen-Po Lin, Hsinchu City (TW); Song-Hai Chai, Dayton, OH (US); Hao-Hsun Chang, Centerville, OH (US); Bor Z. Jang, Centerville, OH (US)

(73) Assignee: Honeycomb Battery Company, Dayton, OH (US)

(21) Appl. No.: 19/046,439

(22) Filed: Feb. 5, 2025

(51) Int. Cl. H01M 4/04; C23C 16/04; C23C 16/24; H01M 4/02; H01M 4/38; H01M 10/0525; H01M 10/054

(52) U.S. Cl. CPC H01M 4/0421; C23C 16/045; C23C 16/24; H01M 4/386; H01M 10/0525; H01M 10/054; H01M 2004/027

(57) ABSTRACT

An apparatus for production of a solid powder mass, comprising: (A) a vaporization chamber for generating or maintaining a silicon halide vapor; (B) a thermal decomposition chamber for thermally decomposing the silicon halide vapor into Si atoms and halogen; (C) a deposition chamber, for receiving Si atoms and for holding multiple porous particles, and a heating device for heating the multiple porous particles disposed therein to facilitate deposition of Si atoms in the pores of the porous particles; and (D) a particle-moving device for mobilizing the multiple porous particles to move around in the deposition chamber to facilitate uniform infiltration and deposition of the Si atoms in pores of the porous particles to form silicon coatings, particles, and/or nanowires (SiNW) therein.

### FIELD

The present invention provides an apparatus and process for producing multiple porous conductive host particles containing Si (in the form of coatings, particles, and/or nanowires) that is uniformly deposited in the pores of the porous host (e.g., porous particles of carbon, graphite, graphene, or metal) for use in the anode (negative electrode) of a rechargeable lithium or sodium battery.

### BACKGROUND

Concerns over the safety of earlier lithium secondary batteries led to the development of lithium ion secondary batteries, in which pure lithium metal sheet or film was replaced by carbonaceous materials as the negative electrode (anode). The carbonaceous material may comprise primarily graphite that is intercalated with lithium and the resulting graphite intercalation compound may be expressed as LiₓC₆, where x is typically less than 1. In order to minimize the loss in energy density due to this replacement, x in LiₓC₆ must be maximized and the irreversible capacity loss Qᵢᵣ in the first charge of the battery must be minimized. The maximum amount of lithium that can be reversibly intercalated into the interstices between graphene planes of a perfect graphite crystal is generally believed to occur in a graphite intercalation compound represented by LiₓC₆ (x=1), corresponding to a theoretical specific capacity of 372 mAh/g.

In addition to carbon- or graphite-based anode materials, other inorganic materials that have been evaluated for potential anode applications include metal oxides, metal nitrides, metal sulfides, and a range of metals, metal alloys, and intermetallic compounds that can accommodate lithium atoms/ions. In particular, lithium alloys having a composition formula of LiₐA (A is a metal such as Al, and “a” satisfies 0<a<5) has been investigated as potential anode materials. This class of anode active materials has a higher theoretical capacity, e.g., Li₄Si (maximum capacity=3,829 mAh/g), Li_{4.4}Si (maximum capacity of Si=4,200 mAh/g), Li_{4.4}Ge (maximum capacity of Ge=1,623 mAh/g), Li_{4.4}Sn (maximum capacity of Sn=993 mAh/g), Li₃Cd (maximum capacity of Cd=715 mAh/g), Li₃Sb (maximum capacity of Sb=660 mAh/g), Li_{4.4}Pb (569 mAh/g), LiZn (410 mAh/g), and Li₃Bi (385 mAh/g).

An anode active material is normally used in a powder form, which is mixed with conductive additives and bonded by a binder resin. The binder also serves to bond the mixture to a current collector. Alternatively, an anode active material may be coated as a thin film onto a current collector. On repeated charge and discharge operations, the alloy particles tend to undergo pulverization and the current collector-supported thin films are prone to fragmentation due to expansion and contraction of the anode active material during the insertion and extraction of lithium ions. This pulverization or fragmentation results in loss of particle-to-particle contacts between the active material and the conductive additive or contacts between the anode material and its current collector. These adverse effects result in a significantly shortened charge-discharge cycle life.

To overcome the problems associated with such mechanical degradation, several approaches have been proposed, including (a) using nano-scaled particles of an anode active material, (b) composites composed of small electrochemically active particles supported by less active or non-active matrices or coatings, (c) metal alloying, and (d) using amorphous anode active material (instead of crystalline form). For instance, there has been work reported on synthesizing amorphous and nanostructured forms of silicon such as nanoparticles, nanowires and nanotubes. This was mostly based on the well-known electrochemical lithiation induced crystalline-to-amorphous silicon phase transformation during the first few cycles as well as conditions employed for synthesis of amorphous silicon.

It is generally believed that the nanostructured and amorphous forms of silicon provide mechanical integrity without pulverization due to the reduced number density of atoms within a nano-sized grain and the ‘free volume’ effects in amorphous silicon which results in better capacity retention and cycle life. Further, due to the presence of defects and absence of long range order in amorphous silicon, the volume expansion upon lithium insertion can be distributed homogenously and the net effect of crack formation and propagation can be less catastrophic compared to crystalline silicon. Hence, the amount of pulverization of the active material is significantly reduced which gives rise to enhanced capacity retention and cyclability.

Amorphous silicon is generally obtained by physical and chemical vapor deposition methods. Physical vapor deposition methods include RF or magnetron sputtering and pulsed laser deposition using silicon targets. Chemical vapor deposition methods include thermal, microwave or plasma assisted decomposition of silicon precursors such as silane, SiH₄. These techniques, though commonly implemented in the electronics industry, are not economically viable for secondary batteries due to the typically high cost of available silane gas, which includes the costs of silane production, silane transport, and silane storage. Silane is a pyrophoric gas, capable of auto-ignition at temperatures below 54° C. (130° F.). A number of fatal industrial accidents produced by combustion and detonation of leaked silane in air have been reported. Furthermore, Silane is highly toxic. For these reasons, the safe transport and safe storage measures add to significant costs of available silane.

Secondary batteries used for consumer portable electronic devices and electric vehicles are subject to very stringent demands of competitive price reduction. Therefore, there is a need to explore alternative cost-effective and safe approaches for generation of amorphous silicon.

When the lithium-ion cell is assembled and filled with electrolyte, the anode and cathode active materials have a difference in potential of at most about 2 volts between the two. The difference in potential between the two electrodes, after the lithium-ion cell has been charged, is about 4 volts. When the lithium-ion cell is charged for the first time, lithium is extracted from the cathode and introduced into the anode. As a result, the anode potential is lowered significantly (toward the potential of metallic lithium), and the cathode potential is further increased (to become even more positive). These changes in potential may give rise to parasitic reactions on both electrodes, but more severely on the anode. For example, a decomposition product known as solid electrolyte interface (SEI) readily forms on the surfaces of anode carbon materials, wherein the SEI layer comprises lithium and electrolyte components. These surface layers or covering layers are lithium-ion conductors which establish an ionic connection between the anode and the electrolyte and prevent the reactions from proceeding any further.

Formation of this SEI layer is therefore necessary for the stability of the half-cell system comprising the anode and the electrolyte. However, as the SEI layer is formed, a portion of the lithium introduced into the cells via the cathode is irreversibly bound and thus removed from cyclic operation, i.e. from the capacity available to the user. This means that, during the course of the first discharge, not as much lithium moves from the anode back to the cathode as had previously been released to the anode during the first charging operation. This phenomenon is called irreversible capacity and is known to consume about 10% to 30% of the capacity of a lithium ion cell.

A further drawback is that the formation of the SEI layer on the anode after the first charging operation may be incomplete and will continue to progress during the subsequent charging and discharge cycles. Even though this process becomes less pronounced with an increasing number of repeated charging and discharge cycles, it still causes continuous abstraction, from the system, of lithium which is no longer available for cyclic operation and thus for the capacity of the cell. Additionally, as indicated earlier, the formation of a solid-electrolyte interface layer consumes about 10% to 30% of the amount of lithium originally stored at the cathode, which is already low in capacity (typically <200 mAh/g). Clearly, it would be a significant advantage if the cells do not require the cathode to supply all the required amount of lithium.

Therefore, in summary, a need exists for a Si-based anode active material (and required process and apparatus) that has a high specific capacity, a minimal irreversible capacity (or a low decay rate), and a long cycle life. One should also be able to produce this anode material cost-effectively and in a safe manner. Si, in the form of Si nanowires, nano-coatings or nano particles, can be more resistant to lithium or sodium absorption or desorption during battery cycling. However, there has been no cost-effective, silane-free method and related apparatus of producing Si nanowires or Si nano-coatings in pores of a conductive porous host. Further, based on the notion that silane gas can be toxic and explosive, a need exists for a production process apparatus that do not involve the use of silane as a feedstock material. In order to accomplish these goals, we have worked diligently and intensively on the development of new electrode materials, which are in a powder form and can be incorporated with an optional binder and optional conductive additive to form an anode (negative electrode) of high areal capacity. Additionally, these anode materials now can be produced with a silane-free process. These research and development efforts lead to the present patent application.

### SUMMARY

The present disclosure provides an anode active material for the anode (negative electrode) of a lithium battery or sodium battery and a method of producing such an anode active material, the anode, and the battery cell. This new material enables the battery to deliver a significantly improved specific capacity and much longer charge-discharge cycle life.

The disclosure also provides a method and apparatus of producing a solid powder mass of multiple porous particulates having pores containing silicon coatings, particles, and/or nanowires (SiNW) therein for use as an anode active material of a lithium-ion or sodium-ion battery.

The method comprises: (A) thermally decomposing a silicon halide vapor to generate Si atoms and halogen and introducing the Si atoms into a deposition chamber or zone wherein multiple porous particles are disposed; and (B) mobilizing the multiple porous particles to move around in the deposition chamber (or zone) to facilitate uniform infiltration and deposition of the Si atoms inside the pores of the porous particles to form silicon coatings, particles, and/or nanowires (SiNW) therein.

In certain embodiments, the apparatus comprises: (A) a vaporization chamber or zone equipped with a heating device for vaporizing a silicon halide source to generate a silicon halide vapor or keeping a silicon halide vapor above its boiling point; (B) a thermal decomposition chamber or zone equipped with a heating device for thermally decomposing the silicon halide vapor into Si atoms and halogen; (C) a deposition chamber or zone, for receiving Si atoms and for holding multiple porous particles, and a heating device for heating said deposition chamber or zone and the multiple porous particles disposed therein to facilitate deposition of Si atoms in the pores of the multiple porous particles; and (D) a particle-moving device for mobilizing said multiple porous particles to move around in the deposition chamber or zone to facilitate uniform infiltration and deposition of said Si atoms in pores of said porous particles to form silicon coatings, particles, and/or nanowires (SiNW) therein.

The vaporization chamber or zone and the thermal decomposition chamber or zone may be adjacent to each other, contiguous to each other, or integrated into one chamber or zone.

In some embodiments, the apparatus further comprise a source of silicon halide vapor and an optional carrier gas source, disposed outside of the vaporization chamber and the decomposition chamber, for delivering the silicon halide vapor into the vaporization chamber or zone vapor and/or the thermal decomposition chamber or zone.

In certain embodiments, the apparatus further comprise a holder in the vaporization chamber for holding a desired amount of silicon halide liquid or solid state. The holder may receive heat from a heating device to vaporize the silicon halide liquid or solid state.

In some embodiments, the apparatus further comprises a reaction zone, for holding a desired amount of Si source, and a conduit for introducing a stream of halogen gas into the reaction zone wherein the halogen gas chemically reacts with the Si source at a reaction temperature to produce a silicon halide that is vaporized to form silicon halide vapor, wherein the Si source comprises Si or a Si-rich compound containing no less than 50% by weight of Si.

In certain embodiments, the disclosure provides a silane-free method of producing a solid powder mass of multiple porous particulates having pores containing silicon (Si) coatings, Si particles, and/or Si nanowires (SiNW) therein for use as an anode active material of a lithium-ion or sodium-ion battery, the method comprising: (a) placing multiple conductive porous particles in a deposition zone of a reaction apparatus, wherein a particle has a diameter from 50 nm to 100 μm and a volume fraction of pores from 5% to 99.9%, and the porous particles comprise a material selected from a carbonaceous, graphitic, graphene, metallic material, or a combination thereof, and wherein the deposition zone is heated to a desired deposition temperature and is equipped with a particle-moving device that, when activated, mobilizes the porous particles around inside the deposition zone; (b) providing a stream of vapor phase, comprising vapor of a silicon halide, and directing the vapor phase to flow into the deposition zone, wherein the silicon halide is selected from SiF₄, SiCl₄, SiI₄, SiI₂, SiBr₄, SiXₐZ_{b}, or a combination thereof, wherein X and Z are each a halogen element, selected from F, Cl, Br, or I, and a=1-3, b=1-3, and a+b=4; and (c) activating the particle-moving device and exposing the silicon halide vapor to a decomposition temperature to convert the silicon halide vapor into a halogen gas and Si atoms, allowing Si atoms to permeate or infiltrate into the pores of the porous particles and deposit therein as solid Si coatings, particles, and/or nanowires (SiNW) to form the solid powder mass of multiple porous particulates, wherein a Si nanowire, particle, or coating has a diameter or thickness from 2 nm to 2 μm and wherein the deposition temperature is the same as or different than the decomposition temperature.

In certain embodiments, step (b) of providing a stream of vapor phase comprises a procedure selected from (i) placing an amount of silicon halide (in a liquid or solid state) in a vaporization chamber of the reaction apparatus and bringing the silicon halide above its boiling point to generate s stream of vapor phase comprising vapor of the silicon halide; (ii) introducing a stream of vapor phase, comprising vapor of the silicon halide and an optional carrier gas, from a container outside of the reaction apparatus through a heated conduit into the deposition zone of the reaction apparatus; or (iii) placing a desired amount of Si source in a reaction zone and introducing a stream of halogen gas into the reaction zone wherein the halogen gas chemically reacts with Si source at a reaction temperature to produce a silicon halide that is vaporized to form silicon halide vapor, wherein the Si source comprises Si or a Si-rich compound containing no less than 50% by weight of Si. In (i) and (ii), the desired silicon halide may be produced, on a separate basis, from a Si source that is reacted with a halogen gas. Alternatively, certain silicon halide is commercially available.

The particle-moving device may be selected from a rotational furnace, rotational tube, fluidized bed apparatus, pneumatic conveyor (using air pressure to transport powders through enclosed lines), screw feeder, vibratory feeder, gravity chute, belt conveyor, bucket elevator, dipleg, cyclone, turbulent gas jet, spouted bed, packed bed reactor, or a combination thereof.

The disclosed method in general does not make use of hydrogen in the production of silicon halide and absolutely no silane is produced or used in the production of Si. Hydrogen may be optionally used during decomposition of certain silicon halide (e.g., SiCl₄) to produce Si. Silane or its derivative chemicals can be explosive and toxic. Typically, when a proper metal catalyst is dispersed in the pores of a porous host, Si is formed inside the host pores in the form of Si nanowires (SiNWs) having a diameter from 2 nm to 500 nm, more typically from 5 nm to 200 nm, and most typically from 20 nm to 100 nm.

The halogen gas product (a decomposition reaction by-product) may be collected into a container and/or used later as a reactant gas (or vapor) of a halogen that chemically reacts with additional Si to produce additional silicon halide. Basically, the halogen gas can be recycled and reused.

Thus, in certain embodiments, the apparatus further comprise a gas exhaust port and halogen gas collection device for exhausting and collecting the halogen gas, a byproduct of thermal decomposition.

In some preferred embodiments, the apparatus further comprises (i) a gas exhaust port and halogen gas collection device for exhausting and collecting the halogen gas, a byproduct of thermal decomposition; and (ii) a halogen delivery device (e.g., 107 in FIG. 4(A)) for transporting the collected halogen gas 82, through halogen gas inlet, into the reaction zone for reuse.

In certain embodiments, the porous conductive particles comprise a first catalyst dispersed in the pores of the particles and the first catalyst comprises a catalytic material comprising a metal element selected from Cu, Sn, Ga, Zn, Mg, Ni, Co, Mn, Fe, Ti, Al, Ag, Au, In, Pt, Pd, or a combination thereof. The catalyst residing in the pores of a conductive porous particle acts to initiate and grow Si nanowires (SiNWs) inside the pores.

In certain preferred embodiments, the first catalyst comprises a catalytic material comprising a metal element selected from Cu, Sn, Ga, Zn, Mg, Ni, Co, Mn, Fe, Ti, Al, Ag, Au, In, Pt, Pd, or a combination thereof. In some embodiments, the first catalyst comprises a catalytic metal in the form of nano particles having a diameter from 0.5 nm to 200 nm (preferably and more typically from 1 nm to 100 nm, further preferably less than 20 nm, and most preferably no greater than 5 nm).

In certain embodiments, the first catalyst dispersed inside the pores of the host is produced by a procedure selected from physical vapor deposition, chemical vapor deposition, sputtering, plasma deposition, laser ablation, plasma spraying, ultrasonic spraying, printing, electrochemical deposition, electrode plating, electrodeless plating, chemical plating, solution deposition, thermal decomposition, or a combination thereof.

The first catalyst may be produced from a catalytic metal precursor comprising a salt or organo-metal molecule of a metal selected from Cu, Sn, Ga, Zn, Mg, Ni, Co, Mn, Fe, Ti, Al, Ag, Au, In, Pt, Pd, or a combination thereof. The salt preferably comprises a nitrate, acetate, sulfate, phosphate, hydroxide, or carboxylate of a metal selected from Cu, Sn, Ga, Zn, Mg, Ni, Co, Mn, Fe, Ti, Al, Ag, Au, In, Pt, Pd, or a combination thereof.

For the purpose of promoting or accelerating the production of silicon halide from chemically reacting a Si source and a halogen gas, the Si source, in a powder form, is preferably in physical contact with a second catalyst or the second catalyst is dispersed in the Si source powder of particles.

The second catalyst comprises a metal, a metal alloy, a metal oxide, a metal salt, a metal hydride, a metal-containing compound, or a combination thereof, wherein the metal is selected from a group of elements consisting of noble metal elements, alkaline and alkaline earth metal elements, transition metal elements, rare earth metal elements, low melting point metal elements, and combinations thereof.

In the disclosed method, the decomposition temperature is typically from 290° C. to 1,500° C. and the deposition temperature is from 200° C. to 1,300° C. The temperature at which a halogen gas reacts with Si to form a silicon halide is typically from 20° C. to 1,500° C. and more typically from 300° C. to 1,250° C.

The porous graphene structure preferably comprises pore walls comprising graphene planes or graphene sheets selected from pristine graphene, graphene fluoride, graphene chloride, graphene bromide, graphene iodide, nitrogenated graphene, hydrogenated graphene, doped graphene, chemically functionalized graphene, graphene oxide, reduced graphene oxide, or a combination thereof.

The porous carbonaceous or graphitic particles preferably comprise particles of activated carbon, soft carbon (defined as a carbon material that is graphitizable), hard carbon (non-graphitizable even at a temperature higher than 2,500° C.), activated natural graphite, activated artificial graphite, exfoliated graphite worms, expanded graphite flakes, meso-phase carbon, needle coke, or a combination thereof.

The porous metallic particles, as a host, can be selected from Cu, Al, steel, Sn, Zn, Ti, Mn, Co, Ni, or any other transition metal. The metal may be coated with a passivation layer (e.g., carbon or polymer).

The method may further comprise a procedure of encapsulating or coating the porous anode material particulates with a thin protecting layer having a thickness from 0.5 nm to 2 μm, wherein the protecting lay comprises carbon, graphene, electron-conducting polymer, lithium ion-conducting polymer, or a combination thereof.

In some embodiments, the method further includes a procedure of prelithiating the Si (Si coatings, particles, or nanowires) deposited in the pores of the multiple particulates, wherein the Si is prelithiated to contain an amount of lithium from 1% to 100% of a maximum lithium content contained in the Si, or is selected from LiₓSi, wherein numerical x is from 0.01 to 4.4.

The method may further comprise a procedure of encapsulating or coating the prelithiated multiple particulates with a thin protecting layer having a thickness from 0.5 nm to 2 μm. The protecting layer preferably comprises a carbon material, graphene, a polymer, or a lithium- or sodium-containing species chemically bonded to said particulates and said lithium- or sodium-containing species is selected from Li₂CO₃, Li₂C₂O₄, LiOH, LiCl, LiI, LiBr, ROCO₂Li, HCOLi, ROLi, (ROCO₂Li)₂, (CH₂OCO₂Li)₂, Li₂S, LiₓSO_{y}, Li₄B, Na₄B, Na₂CO₃, Na₂O, Na₂C₂O₄, NaOH, NaX, ROCO₂Na, HCONa, RONa, (ROCO₂Na)₂, (CH₂OCO₂Na)₂, Na₂S, NaₓSO_{y}, a combination thereof, a combination thereof with Li₂O or LiF, or a combination of Li₂O and LiF, wherein X=F, Cl, I, or Br, R=a hydrocarbon group, x=0-1, y=1-4.

The protecting layer may comprise a thin layer of a high-elasticity polymer having a fully recoverable tensile strain from 5% to 1,000%, and a lithium ion conductivity from 10⁻⁷ S/cm to 5×10⁻² S/cm at room temperature.

The step of prelithiating may include a procedure selected from chemical prelithiation, electrochemical lithiation, solution lithiation, physical lithiation, or a combination thereof.

The present disclosure provides a silane-free method of producing a solid powder mass of multiple porous particulates having pores containing silicon coating, particles, and/or nanowires (SiNW) therein for use as an anode active material of a lithium-ion or sodium-ion battery The method comprises: (a) placing multiple conductive porous particles in a deposition zone of a reaction apparatus and mobilizing the porous particles around inside the deposition zone; (b) introducing a stream of vapor phase, comprising vapor of a silicon halide, into the deposition zone, wherein the silicon halide is selected from SiF₄, SiCl₄, SiI₄, SiI₂, SiBr₄, SiXₐZ_{b}, or a combination thereof, wherein X and Z are each a halogen element, selected from F, Cl, Br, or I, and a=1-3, b=1-3, and a+b=4; and (c) exposing the silicon halide vapor to a decomposition temperature to convert the silicon halide vapor into a halogen gas and Si atoms and facilitating Si atoms to infiltrate into the pores of the porous particles and deposit therein as solid Si coatings, particles, and/or nanowires (SiNW) to form the solid powder mass of multiple porous particulates. Preferably, the halogen gas product is collected into a container or reused as a reactant gas of a halogen that chemically reacts with additional Si to produce additional silicon halide.

The procedure of mobilizing the porous particles is preferably conducted with a particle-moving device selected from a rotational furnace, rotational tube, fluidized bed apparatus, pneumatic conveyor (using air pressure to transport powders through enclosed lines), screw feeder, vibratory feeder, gravity chute, belt conveyor, bucket elevator, dipleg, cyclone, turbulent gas jet, spouted bed, packed bed reactor, or a combination thereof.

In the disclosed method, step (A) and step (B), in combination, may comprise the following procedures: (a) providing multiple porous conductive particles having a volume fraction of pores from 5% to 99.9%, wherein the porous conductive particles are selected from a carbonaceous, graphitic, graphene, or metallic material in a bulk form or in a form of multiple porous particles; (b) placing said porous multiple porous particles and a silicon halide in a reaction chamber, wherein the reaction chamber is equipped or provided with a particle-moving device and the porous particles and the silicon halide are pre-mixed to form a mixture or placed in different locations of the reaction chamber and wherein the silicon halide is selected from SiF₄, SiCl₄, SiI₄, SiI₂, SiBr₄, SiXₐZ_{b}, or a combination thereof, wherein X and Z are each a halogen element and a=1-3, b=1-3, and a+b=4; and (c) activating the particle-moving device to move the porous conductive particles around inside a confined region of the reaction chamber while also vaporizing said silicon halide to form a vapor phase at a first temperature and thermally decomposing the silicon halide vapor at a second temperature into a halogen gas product and Si atoms, wherein said Si atoms infiltrate into pores of the porous particles to form Si coatings, particles, and/or nanowires (SiNW) therein, wherein the Si nanowires, particles, or coatings have a diameter or thickness from 2 nm to 2 μm and wherein the second temperature is the same as or different than the first temperature.

In certain embodiments, procedure (b) comprises a procedure of mixing the silicon halide, in a liquid, solution, or solid state, with said porous conductive particles to form a mixture in such a manner that at least a portion of said silicon halide is impregnated into pores of the porous particles, prior to loading the mixture into the reaction chamber.

The method may further comprise a step of forming multiple anode material particulates, along with a binder and optional conductive additive, into an anode electrode. The method may further comprise a step of combining the anode electrode with a cathode, and an electrolyte to form a battery cell.

The present disclosure provides a solid powder mass of multiple anode material particulates (containing Si therein) produced by the method herein disclosed. Also provided is an anode or negative electrode, comprising multiple anode material particulates produced by the disclosed method, an optional conductive additive, and an optional binder. Further provided is a lithium-ion, lithium metal, sodium-ion, or sodium metal battery containing this anode, a cathode, and an electrolyte in ionic contact with the anode and the cathode.

In general, the deposited Si does not fully occupy the pores; preferably occupying only 5-90% by volume of the pores and further preferably 30-70% by volume, allowing a sufficient amount of voids to accommodate the volume expansion of the anode active material during the battery charging procedure.

These particulates are in a powder form that can be readily incorporated with an optional binder and optional conductive additive to form an anode (negative electrode) of high areal capacity, typically higher than 4.5 mAh/cm², more typically higher than 6 mAh/cm², further typically and desirably higher than 10 mAh/cm², still more typically and desirably higher than 20 mAh/cm², 30 mAh/cm², 50 mAh/cm², etc. These high areal capacities normally could not be achieved if one chooses to deposit pure Si directly on a current collector.

### BRIEF DESCRIPTION OF THE DRAWINGS

FIG. 1: Schematic of a lithium-ion cell comprising an anode (featuring a plurality of porous carbon or graphene host particles each having Si coatings, particles, and/or nanowires residing in pores), a separator, and a cathode.

FIG. 2: A process flow chart showing preferred routes to prepare silicon residing in pores of porous conductive particles according to some preferred embodiments.

FIG. 3(A): Schematic of an example of porous graphene/carbon host particle containing Si residing in the pores of the host according to some preferred embodiments;

FIG. 3(B) Schematic of 5 illustrative examples of porous graphene composite balls that can serve as a host structure to accommodate the Si coatings, particles, and/or nanowires in pores of the host according to some preferred embodiments.

FIG. 4(A): Schematic of an apparatus system for producing anode active materials comprising a plurality of porous conductive particles inhabited with Si coatings, particles, and/or nanowires; the system featuring a deposition zone equipped with a particle-moving device (e.g., fluidized-bed) that moves porous conductive particles around inside the deposition zone while these particles are being infiltrated with energetic Si atoms;

FIG. 4(B): Schematic of an apparatus system for producing anode active materials comprising a plurality of porous conductive particles inhabited with Si coatings, particles, and/or nanowires; the system featuring a deposition zone equipped with a particle-moving device (e.g., a rotating furnace) that moves porous conductive particles around inside the deposition zone while these particles are being infiltrated with energetic Si atoms;

FIG. 4(C): Schematic of an apparatus system comprising (i) a reactor having an evaporator or vaporization chamber 112 (in which silicon halide, SiCl₄, resides and gets vaporized) and (ii) a decomposer/deposition chamber 110 (where silicon halide vapor thermally decomposes into Si and halogen gas), enabling the generation and deposition of Si in the pores of porous graphene, carbon, or metal host particles, according to some embodiments of the present disclosure; the porous host particles are being moved around using a particle-moving device (fluidized-bed system as an example); if H₂ is introduced into the decomposition chamber, HCl is produced;

FIG. 4(D): Schematic of an apparatus system comprising a reactor having a combined vaporization/decomposition chamber 114 (in which silicon halide, SiI₄, resides and gets vaporized) and a deposition chamber 116 (where silicon halide vapor thermally decomposes into Si and halogen gas) enabling the generation and deposition of Si in the pores of porous graphene, carbon, or metallic host particles, according to some embodiments of the present disclosure; the porous host particles are being moved around using a particle-moving device (fluidized-bed system as an example);

FIG. 4(E): Schematic of an apparatus that can be used to produce Si-rich composite particles comprising porous conductive particles containing Si therein, according to some embodiments of the present disclosure; the apparatus comprises a reaction chamber where porous host particles having pores initially loaded with silicon halide liquid or solid reside and the chamber is equipped or provided with a particle-moving device; the reaction chamber is also a combined vaporization/decomposition/deposition chamber;

FIG. 4(F): Schematic of the apparatus (as in FIG. 4(E)) that enables vaporization and decomposition of silicon halide, and deposition of Si in pores of multiple porous conductive particles to produce Si-rich porous composite particles; the entire container or the deposition zone alone may be subjected to a rotational motion, vibration, or fluidizing gas-driven powder movement while porous particles are being infiltrated with Si atoms, according to some embodiments of the present disclosure; the reaction chamber is also a combined vaporization/decomposition/deposition chamber.

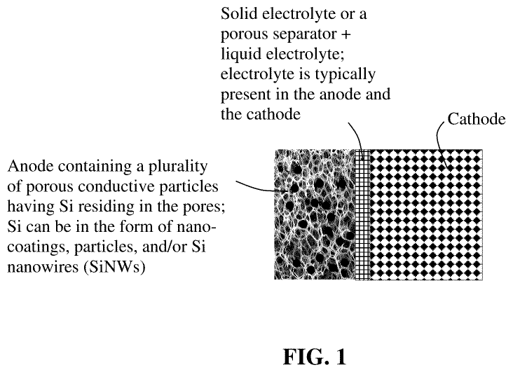

### DETAILED DESCRIPTION

This disclosure is related to silicon (Si)-based anode materials for high-capacity lithium batteries or sodium batteries, which are preferably secondary batteries based on a non-aqueous electrolyte, a polymer gel electrolyte, solid polymer electrolyte, quasi-solid electrolyte, inorganic solid-state electrolyte, or composite or hybrid electrolyte. The shape of a lithium metal or lithium ion battery can be cylindrical, square, button-like, etc. The present invention is not limited to any battery shape or configuration.

The present disclosure provides a method and apparatus for the production of a solid powder mass of multiple porous particulates having pores containing silicon coatings, particles, and/or nanowires (SiNW) therein for use as an anode active material of a lithium-ion or sodium-ion battery. In certain embodiments, the method comprises: (A) thermally decomposing a silicon halide vapor to generate Si atoms and halogen and introducing the Si atoms into a deposition chamber or zone wherein multiple porous particles are disposed; and (B) mobilizing the multiple porous particles to move around in the deposition chamber or zone to facilitate uniform infiltration and deposition of the Si atoms in pores of the porous particles to form silicon coatings, particles, and/or nanowires (SiNW) therein.

In certain embodiments, the apparatus comprises: (A) a vaporization chamber or zone equipped with a heating device for vaporizing a silicon halide source to generate a silicon halide vapor or keeping a silicon halide vapor above its boiling point; (B) a thermal decomposition chamber or zone equipped with a heating device for thermally decomposing the silicon halide vapor into Si atoms and halogen; (C) a deposition chamber or zone, for receiving Si atoms and for holding multiple porous particles, and a heating device for heating said deposition chamber or zone and the multiple porous particles disposed therein to facilitate deposition of Si atoms in the pores of the multiple porous particles; and (D) a particle-moving device for mobilizing said multiple porous particles to move around in the deposition chamber or zone to facilitate uniform infiltration and deposition of said Si atoms in pores of said porous particles to form silicon coatings, particles, and/or nanowires (SiNW) therein.

In certain embodiments, the vaporization chamber, the thermal decomposition chamber, and the deposition chamber are three separate chambers or zones in the same apparatus. In some embodiments, the three chambers may be merged to become two chambers or just one chamber. However, in each version, there would be a particle-moving device or means to move the multiple porous particles around.

For instance, the vaporization chamber or zone and the thermal decomposition chamber or zone may be adjacent to each other, contiguous to each other, or integrated into one chamber or zone. Thus, there can be an integrated vaporization/decomposition chamber (or zone) and a deposition chamber (zone) and the deposition zone is in a working relation to the particle-moving device. In some embodiments, the vaporization chamber, the thermal decomposition chamber, and the deposition chamber are the same chamber and all three functions are conducted in the same chamber: formation of silicon halide vapor, decomposition of silicon vapor to form Si atoms and halogen, and deposition of Si atoms in the pores of porous particles.

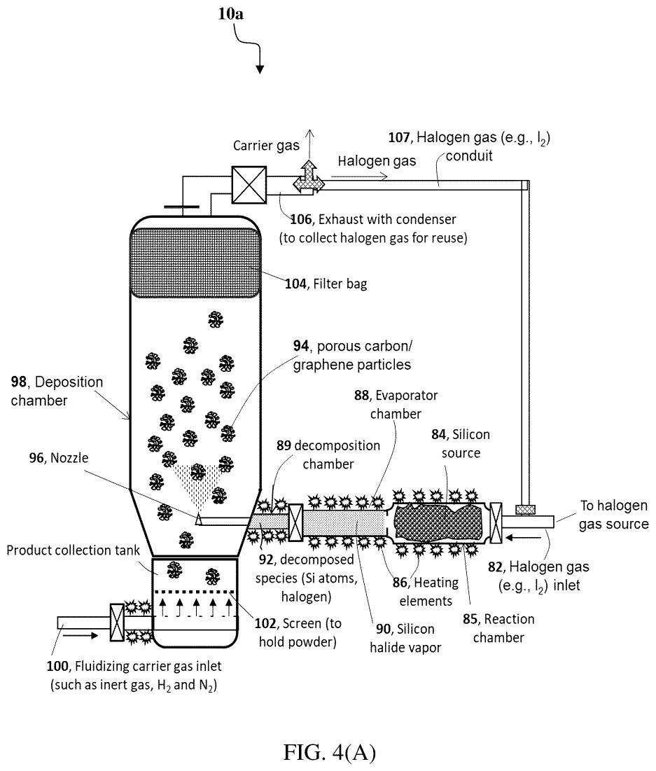

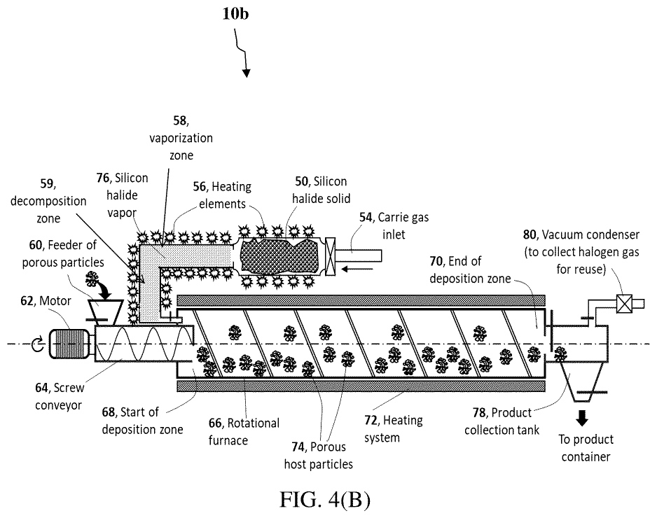

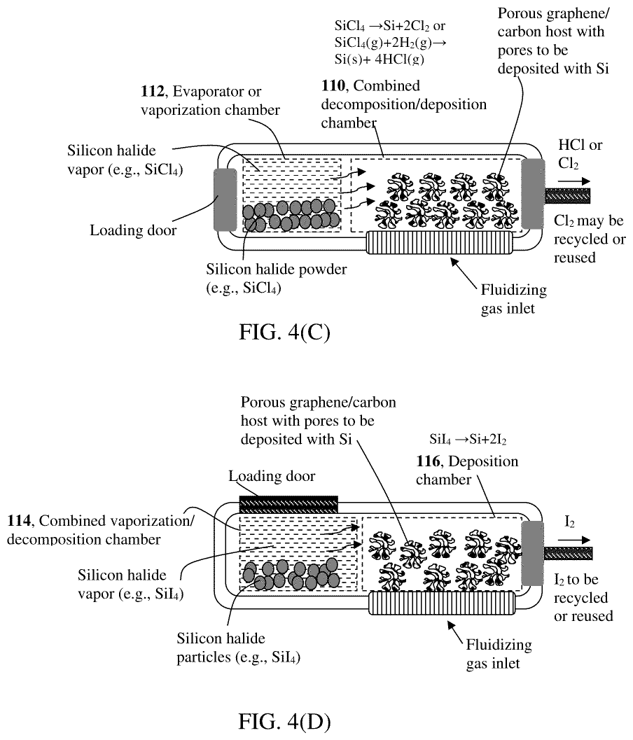

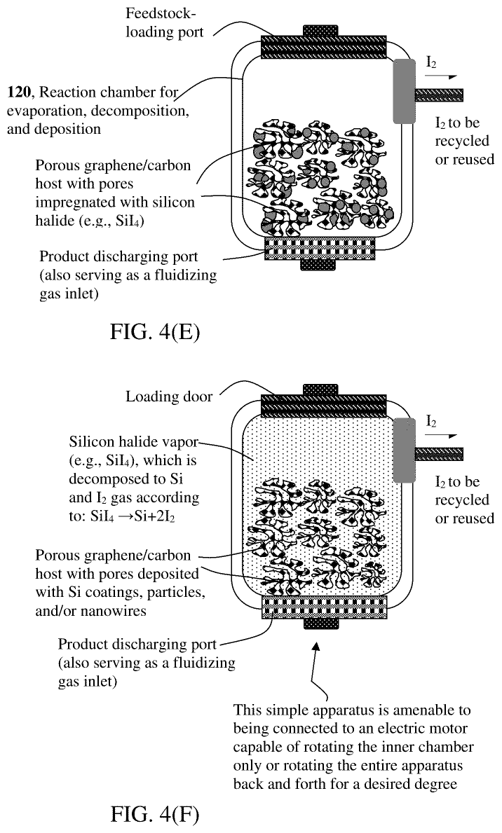

In some embodiments (e.g., FIG. 4(B)), the apparatus further comprise a source 50 of silicon halide vapor and an optional carrier gas source (with an inlet 54), disposed outside of the vaporization chamber and the decomposition chamber, for delivering the silicon halide vapor into the vaporization chamber or zone and/or the thermal decomposition chamber or zone.

In certain embodiments, the apparatus further comprise a holder in the vaporization chamber for holding a desired amount of silicon halide liquid or solid state. The holder may receive heat from a heating device to vaporize the silicon halide liquid or solid state.

In some embodiments, the apparatus further comprises a reaction zone, for holding a desired amount of Si source, and a conduit for introducing a stream of halogen gas into the reaction zone wherein the halogen gas chemically reacts with the Si source at a reaction temperature to produce a silicon halide that is vaporized to form silicon halide vapor, wherein the Si source comprises Si or a Si-rich compound containing no less than 50% by weight of Si.

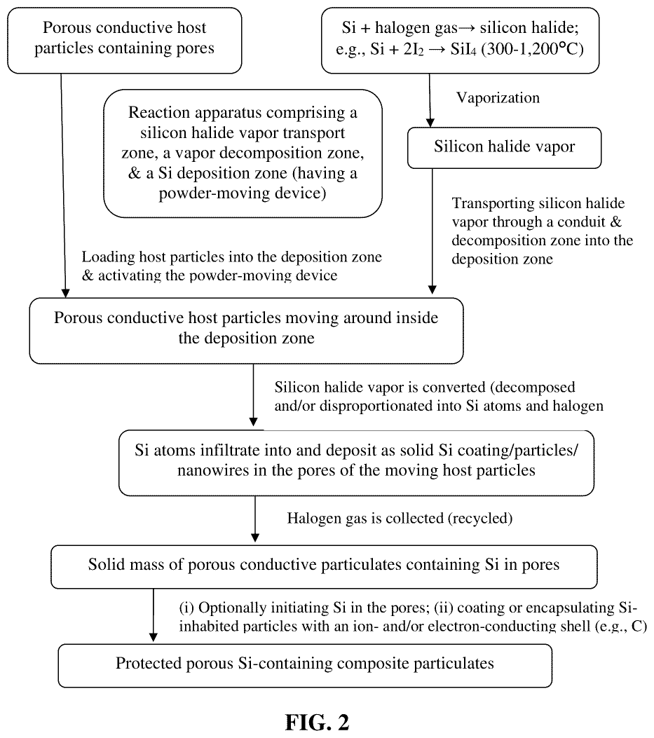

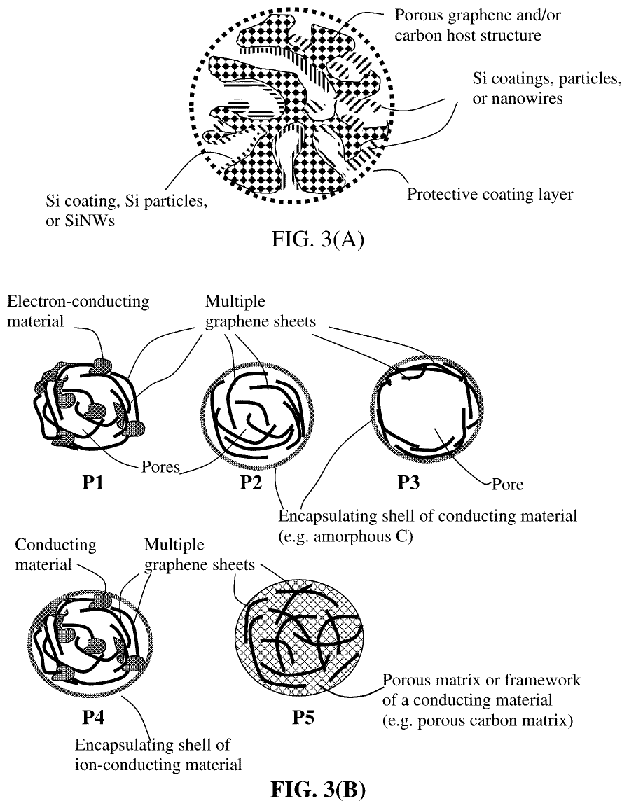

In certain embodiments, as schematically illustrated in the process flow chart of FIG. 2, the disclosure provides a silane-free method of producing a solid powder mass of multiple porous particulates having pores containing silicon (Si) coatings, Si particles, and/or Si nanowires (SiNW) therein for use as an anode active material of a lithium-ion or sodium-ion battery, the method comprising: (a) placing multiple conductive porous particles in a deposition zone of a reaction apparatus, wherein a particle has a diameter from 50 nm to 100 μm and a volume fraction of pores from 5% to 99.9%, and the porous particles comprise a material selected from a carbonaceous, graphitic, graphene, metallic material, or a combination thereof, and wherein the deposition zone is heated to a desired deposition temperature and is equipped with a particle-moving device that, when activated, mobilizes the porous particles around inside the deposition zone; (b) providing a stream of vapor phase, comprising vapor of a silicon halide, and directing the vapor phase to flow into the deposition zone, wherein the silicon halide is selected from SiF₄, SiCl₄, SiI₄, SiI₂, SiBr₄, SiXₐZ_{b}q, or a combination thereof, wherein X and Z are each a halogen element, selected from F, Cl, Br, or I, and a=1-3, b=1-3, and a+b=4; and (c) activating the particle-moving device and exposing the silicon halide vapor to a decomposition temperature to convert the silicon halide vapor into a halogen gas and Si atoms, allowing Si atoms to permeate or infiltrate into the pores of the porous particles and deposit therein as solid Si coatings, particles, and/or nanowires (SiNW) to form the solid powder mass of multiple porous particulates (e.g., FIG. 3(A)), wherein the Si nanowires, particles, or coatings have a diameter or thickness from 2 nm to 2 μm and wherein the deposition temperature is the same as or different than the decomposition temperature.

The particle-moving device may be selected from a rotational furnace, rotational tube, fluidized bed apparatus, pneumatic conveyor (using air pressure to transport powders through enclosed lines), screw feeder, vibratory feeder, gravity chute, belt conveyor, bucket elevator, dipleg, cyclone, turbulent gas jet, spouted bed, packed bed reactor, or a combination thereof.

Fluidized bed apparatus make use of a controlled stream of gas to move solid powder particles around in a confined space or enclosed chamber. A rotational furnace may move solid particles from a screw head to a screw end or simply mobilize individual particles by rotating a tube furnace. A rotational tube may work to move solid particles around inside the tube.

Pneumatic conveying is considered the most common method for transferring bulk powders due to its enclosed design, preventing dust and contamination; ideal for various powder types. Screw feeders may be used for precise metering of powder flow with a rotating screw mechanism. Vibratory feeders utilize vibrations to promote consistent powder flow, often used for fine powders. Gravity chutes are simple design where powder slides down an inclined surface due to gravity. A belt conveyor is a moving belt transporting powder across a desired path. A bucket elevator is a vertical conveying system using buckets attached to a rotating belt to lift powder to different levels. A dipleg is a gravity-fed system used to transfer powders between different process stages. For instance, a dipleg is a vertical pipe that moves particles from a cyclone into a fluidized bed. It is used in many fluidized bed (CFB) systems, including fluid catalytic cracking (FCC). Cyclones are used to separate particles based on size and density by spinning air and powder in a conical chamber, allowing heavier particles to settle out. A turbulent gas jet may also be used in an enclosed space to move the particles around.

In certain embodiments, step (b) of providing a stream of silicon halide vapor phase comprises a procedure selected from:
(i) placing an amount of silicon halide (in a liquid or solid state) in a vaporization chamber of the reaction apparatus and bringing the silicon halide above its boiling point to generate s stream of vapor phase comprising vapor of the silicon halide;
(ii) introducing a stream of vapor phase, comprising vapor of the silicon halide and an optional carrier gas, from a container outside of the reaction apparatus; the vapor gas goes through a heated conduit into the deposition zone of the reaction apparatus prior to reaching the deposition zone; or
(iii) placing a desired amount of Si source (e.g., 84 in an apparatus 10a of FIG. 4(A)) in a reaction zone (e.g., 85) and introducing a stream of halogen gas (82) into the reaction zone wherein the halogen gas chemically reacts with Si source at a reaction temperature to produce a silicon halide that is vaporized to form silicon halide vapor (90), wherein the Si source (84) comprises Si or a Si-rich compound containing no less than 50% by weight of Si.

In (i) and (ii), the desired silicon halide (e.g., to be disposed as 50 in the apparatus 10b of FIG. 4(B)) may be obtained by producing, on a separate basis, from a Si source that is reacted with a halogen gas. Alternatively, certain silicon halide can be purchased form commercial sources.

In (iii), as schematically illustrated in FIG. 4(A), one can dispose a Si source 84 (e.g., powder of metallurgical-grade Si) in a reaction zone 85 of an apparatus 10a and then introduce halogen gas through an inlet 82 into the reaction zone, wherein halogen gas (F₂, Cl₂, Br₂, and/or I₂) reacts with Si to form silicon halide. With heating provisions in place (e.g., heating elements 86), the in situ produced silicon halide is heated above its boiling point to form a silicon halide vapor, which flows into a vaporization zone or chamber 88 that keeps the silicon halide vapor 90 in a vaporous state and also begins to decompose the silicon halide vapor. The thermal decomposition of the silicon halide vapor into energetic species 92 (Si atoms and halogen) is substantially completed in a decomposition zone 89 (chamber).

The energetic species 92 (Si atoms and halogen) are then sprayed through a nozzle 96 into a deposition chamber 98 where Si atoms get to infiltrate into the pores of porous conductive particles 94 (e.g., porous carbon, graphite, metal, or graphene particles). With a proper decomposition temperature, Si atoms get to deposit as solid Si coating, Si particles, and/or Si nanowires (if a catalyst is present) while halogen (having a significantly lower vaporization temperature) remains in a gaseous state that moves through a filter bag 104 and an exhaust port 106 with a condenser to collect halogen for reuse and to discharge other gases (e.g., carrier gas, which can be collected, if so desired). The collected halogen gas may be transported back to the inlet 82 for reuse.

The particle-moving device in the reaction apparatus 10a of FIG. 4(A) is basically a fluidized bed-based system wherein a fluidizing gas is pumped through an inlet 100 and a screen 102 to enter the deposition chamber 98 to force the porous conductive particles (solid powder) to flow and move around in the chamber like a fluid (hence, the name “fluidized”). By forcing the porous conductive particles to basically dance around in the deposition zone, one achieves an environment wherein the energetic Si atoms get to more uniformly infiltrate into the pores of essentially all the porous conductive particles. This results in very even deposition of Si solid (coating, particle, and/or nanowires) in the pores of conductive particles, as evidenced by the small particle-to-particle variations in the Si amounts deposited in the pores as measured by average weight gains of porous particles.

The selection of suitable reaction temperatures between Si and halogen gases to form silicon halides and the selection of silicon halide decomposition temperatures can be made according to the following discussions:

Silicon reacts with chlorine at temperatures above 300° C. to form silicon tetrachloride (SiCl₄), with the most efficient reaction occurring around 600° C. Silicon tetrachloride (SiCl₄) begins to significantly decompose into silicon (Si) at around 1,250° C. This decomposition typically occurs when SiCl₄ is exposed to high temperatures optionally in the presence of a reducing agent, like hydrogen. While the exact temperature can vary depending on conditions, 1,250° C. is considered the approximate point where SiCl₄ starts to noticeably break down into silicon. In the presence of hydrogen (if so desired), the decomposition reaction can be represented as: SiCl₄ (g)+2H₂ (g)→Si(s)+4 HCl (g).

Fluorine readily reacts with silicon at room temperature, meaning the reaction occurs even at relatively low temperatures, making it one of the most reactive halogen elements with silicon; the primary reaction product is silicon tetrafluoride (SiF₄). Silicon tetrafluoride (SiF₄) does not readily decompose into elemental silicon at typical temperatures; however, at very high temperatures exceeding 1000° C. (around 1200° C. or higher), significant decomposition can occur, with the exact temperature depending on the specific conditions and presence of other reactants.

Iodine reacts with silicon (Si) at temperatures above 300° C. While the reaction can occur at lower temperatures, it becomes significantly faster and more noticeable at temperatures exceeding 300° C., forming silicon tetraiodide (SiI₄) as the product. Unlike some other halogen reactions with silicon, like with fluorine, iodine needs heat to react readily with silicon. The primary product of the reaction is silicon tetraiodide (SiI₄).

Silicon tetraiodide (SiI₄) decomposes into silicon (Si) at a temperature around 287.4° C. (549.3° F.), which is its boiling point; meaning that when heated to this temperature, it readily vaporizes and an break down into its constituent elements, silicon and iodine. However, a higher temperature (e.g., 500-1,250° C.) is recommended for the decomposition and deposition chamber.

Bromine reacts with silicon (Si) at temperatures above 300° C.; while not readily reacting at room temperature, the reaction becomes significant when heated, forming silicon tetrabromide (SiBr₄) as the primary product. It can also be produced by treating silicon-copper mixture with bromine: Si+Br₂→SiBr₄. Silicon reacts with all halogens (including bromine, chlorine, fluorine, and iodine) to form silicon tetrahalides, but the reaction with bromine requires elevated temperatures. SiBr₄ began to decompose at 800° C. simultaneously with the evolution of tribromosilane (SiHBr₃) if H₂ is introduced into the decomposer, which was followed by the deposition of silicon.

In the presently disclosed method, the decomposition (or dissociation) of a silicon halide (e.g., SiI₄) can include, for instance, direct conversion from a silicon tetra-halide into Si and halogen (e.g., SiI₄→Si+2 I₂) or indirect conversion or disproportionation (e.g., through SiI₂→Si+12).

For the gas phase production of silicon nanowires in the pores of porous particles, the silicon precursor (for instance, SiI₄) is in a gaseous state and is thermally decomposed into Si and a halogen gas (e.g., I₂). The halogen gas can be collected and recycled. A first metal catalyst may be used to facilitate the growth of Si nanowires through a process called vapor-liquid-solid (VLS) mechanism; essentially, the silicon atoms from the gas phase condense on the liquid metal catalyst, forming the nanowire structure. Without the presence of this metal catalyst, Si atoms will typically deposit in the pores in the form of a coating and/or particle, rather than Si nanowires.

As discussed in (i) and (ii) above, the production of Si-inhabited porous conductive particles may begin with using silicon halide as a feedstock material (e.g., to be disposed as 50 in FIG. 4(B)), rather than begin with the chemical reaction between a Si source in the reaction apparatus and a halogen gas.

As schematically illustrated in FIG. 4(B), the production method may begin with loading a desired amount of previously made silicon halide liquid or solid 50 in a chamber that is heated (e.g., with heating coils 56) to vaporize the silicon halide 50. If necessary, a carrier gas (e.g., an inert gas, H₂, or a mixture thereof) may be introduced through an inlet 54 to enter the chamber and help to carry the silicon halide vapor into an evaporator zone 58, which also serves to assist in decomposing the silicon halide vapor 76. The silicon halide vapor flows through a decomposition zone or chamber 59 wherein the vapor is decomposed into Si atoms and halogen gas prior to entering a deposition zone (from 68 to 70) inside a rotational furnace 66.

Porous conductive particles are fed through a feeder hopper 60 into a screw conveyor 64 driven by an electric motor 62. The screw conveyor 64 moves and dispenses the porous conductive particles into the starting point 68 of the rotational furnace 66. As the porous particles 74 are driven to move forward from 68 to 70 in the rotational furnace 66 (heated by a heating system 72), Si atoms get to deposit into pores of the porous particles at a deposition temperature. This temperature is typically above the vaporization temperature of the halogen, which is maintained in a vapor state and gets collected through the use of a vacuum condenser 80. Concurrently, the Si-inhabited porous particles are recovered through, for instance, a product collection tank 78.

In certain embodiments, the powder of multiple porous conductive particles (as a host to accommodate Si) and the silicon halide liquid or solid (as a source for Si atoms) may be disposed adjacent to each other in the same reaction apparatus, which is equipped or provided with a particle-moving device to move the porous conductive particles around in a deposition chamber or to move both the porous conductive particles and silicon halide around in their own chamber(s).

As an example, FIG. 4(C) schematically shows a system comprising (i) a reactor having an evaporator or vaporization chamber 112 (in which silicon halide, SiCl₄, resides and gets vaporized) and (ii) a decomposer/deposition chamber 110 (where silicon halide vapor thermally decomposes into Si and halogen gas), enabling the generation and deposition of Si in the pores of porous graphene, carbon, or metal host particles, according to some embodiments of the present disclosure. The porous host particles are being moved around using a particle-moving device (fluidized-bed system as an example). If H₂ is introduced into the decomposition chamber, HCl is produced and collected.

FIG. 4(D) schematically shows a similar system comprising a reactor having a combined vaporization/decomposition chamber 114 (in which silicon halide, SiI₄, resides and gets vaporized) and a deposition chamber 116 (where silicon halide vapor thermally decomposes into Si and halogen gas) enabling the generation and deposition of Si in the pores of porous graphene, carbon, or metallic host particles, according to some embodiments of the present disclosure. The porous host particles are being moved around using a particle-moving device (fluidized-bed system as an example). Other types of particle-moving devices may be used to move the porous host particles. For instance, an inner quartz tube may be used to host the porous conductive particles and this inner tube may be connected to an electric motor (not shown) that rotates this inner tube.

Schematically illustrated in FIG. 4(E) is an apparatus that can be used to produce Si-rich porous composite particles, each comprising a porous conductive host particulate containing Si therein, according to some embodiments of the present disclosure. In this apparatus, the vaporization zone, the thermal decomposition zone and the deposition zone are integrated into just one zone or chamber 120.

Prior to being disposed in the chamber 120 (a multiple-purpose chamber including the functions of heating, vaporizing, decomposition, and deposition), the porous host particles disposed in the reaction chamber have their pores pre-loaded with silicon halide liquid or solid reside. The temperature and pressure in this chamber can be monitored and adjusted to enable evaporation and decomposition of silicon halide and then deposition of Si in the pores of the host particles. The porous host particles are being moved around using a particle-moving device (fluidized-bed system as an example). Again, other types of particle-moving devices may be used to move the porous host particles. For instance, the chamber may be connected to an electric motor (not shown) that rotates this chamber while Si atoms are impregnating and depositing in the pores.

The reaction chamber may be heated by a heating provision (e.g., heating elements) that brings the temperature of the reactants (e.g., Si and halogen gas) to a first temperature (e.g., in the range of 200° C. to 1,650° C., preferably from 500° C. to 1,500° C.) for a first period of time (e.g., typically several minutes, but can be hours if so desired) to allow for the formation of a vapor phase containing silicon halide vapor). The silicon halide vapor phase (before, during, or soon after thermal decomposition into Si and a halogen gas) infiltrates into pores of the host particles, facilitating deposition of Si coatings, nano particles, and/or SiNWs therein at a second temperature for a second period of residence time (e.g., typically several minutes, but can be hours if so desired). This second temperature enables the desired chemical reaction that decomposes silicon halide into Si (along with other byproduct chemical species, such as halogen gases) under a vacuum or inert gas condition. The halogen gas may be collected and reused at a later time.

FIG. 4(F) schematically shows an apparatus (as in FIG. 4(E)) that enables vaporization and decomposition of silicon halide, and deposition of Si, at different temperatures, to produce Si-rich composite particles comprising porous conductive host structure containing Si therein, according to some embodiments of the present disclosure.

In certain preferred embodiments (as illustrated in FIGS. 4(E) and 4(F)), the Si deposition method may begin with a procedure of mixing the silicon halide (in a liquid, solution, or solid state) with the porous conductive particles to form a mixture in such a manner that at least a portion (preferably a majority or all) of the silicon halide is impregnated into pores of the host structure, prior to loading the mixture into a reaction chamber. A solution herein refers to a liquid solution containing a silicon halide dissolved in a liquid solvent. The liquid solvent may be removed after the solution is impregnated into the pores of a host. The liquid solvent can be another type of silicon halide with a suitable melting point.

The procedure of mixing a silicon halide (in a liquid, solution, or solid state state) with the porous host structure to form a mixture may be conducted by any known method of mixing (solid/liquid mixing, solid/solid mixing, solid particles dipping or immersing in a liquid or liquid solution, etc.). There is no restriction on the type of mixing procedures that can be used, provided at least a portion of the silicon halide is made to impregnate into the pores of the host structure.

Table 1 below summarizes the melting point, boiling point, and Si—X bond energy data (X=F, Cl, I, or Br, etc.) of select silicon halides (versus silane, SiH₄) from literature. At room temperature, all the silicon halides are above their melting points (except SiI₄) and, hence, liquid (melt) impregnation of porous host structures by the silicon halide may be conducted at room temperature or above (above 155° C. for SiI₄). Since the boiling point (−90.3° C.) of SiF₄ is not much higher than its melting point (−95° C.), mixing of SiF₄ with porous host particles may be best conducted in a solution state or in a blend with another type of silicon halogen. The SiF₄ gas may be directly introduced into the decomposition chamber (e.g., as illustrated in FIG. 4(D)).

TABLE 1
Melting point, boiling point, and Si—X bond energy (X = F, Cl,
I, or Br, etc.) of select silicon halides (versus silane, SiH₄)

| | SiH₄ | SiF₄ | SiCl₄ | SiBr₄ | SiI₄ | SiCl₃Br | SiCl₂Br₂ | SiClBr₃ |
|---|---|---|---|---|---|---|---|---|
| b.p. (° C.) | −111.9 | −90.3 | 56.8 | 155.0 | 290.0 | 80.3 | 104.4 | 128 |
| m.p. (° C.) | −185 | −95.0 | −68.8 | 5.0 | 125-155 | −62 | −45.5 | −20.8 |
| Si—X bond length (Å) | >0.74 | 1.55 | 2.02 | 2.20 | 2.43 | — | — | — |
| Si—X bond energy | 384 | 582 | 391 | 310 | 234 | — | — | — |
| (kJ/mol) | | | | | | | | |

The melting point of SiBr₂I₂ (silicon dibromide diiodide) is not readily available in standard reference sources as it is a relatively uncommon and poorly studied compound. However, based on its chemical structure, it is expected to have a melting point significantly below room temperature, likely somewhere in the range of −50 to −20° C. (depending on purity and crystal structure). As such, room temperature may be used as the temperature for melt (liquid) impregnation of SiBr₂I₂ and most other silicon halide compounds.

The resultant porous host particles (containing 0.1% to 98% by weight of Si residing in the pores of the host) may be combined with a resin binder and an optional conductive additive to produce an anode using, for instance, the well-known slurry coating process.

In the disclosed method, no silane is produced or used in the production of Si. Silane or its derivative chemicals can be explosive and toxic. Typically, Si is formed inside the host pores in the form of coatings, nano particles, and/or SiNWs having a thickness or diameter from 2 nm to 500 nm, more typically from 5 nm to 200 nm, further more typically from 10 nm to 100 nm, and most desirably less than 50 nm.

The halogen gas product (a reaction by-product) may be collected into a container and used later as a reactant gas or vapor of a halogen that chemically reacts with additional Si to produce additional solid powder mass. Basically, the halogen gas can be recycled and reused.

In certain embodiments, the first catalyst comprises a catalytic material comprising a metal element selected from Cu, Sn, Ga, Zn, Mg, Ni, Co, Mn, Fe, Ti, Al, Ag, Au, In, Pt, Pd, or a combination thereof to facilitate Si nanowire growth inside particle pores. In some embodiments, the first catalyst comprises a catalytic metal in the form of nano particles having a diameter from 0.5 nm to 200 nm (preferably and more typically from 1 nm to 100 nm, further preferably less than 20 nm, and most preferably no greater than 5 nm).

As a first catalyst in the disclosed method, a metal catalyst (e.g., Cu, Sn, Ga, Zn, Mg, Ni, Co, Mn, Fe, Ti, Al, Ag, Au, In, Pt, Pd, or a combination thereof) is typically deposited on the pore walls of a porous host structure to initiate the Si nanowire growth. The silicon atoms from the gas phase dissolve in the liquid metal catalyst droplet (typically near a eutectic point), becoming supersaturated and then precipitating out as a crystalline Si nanowire. Factors like temperature, pressure, gas flow rate, and catalyst size can be carefully controlled to influence the size, morphology, and crystal structure of the resulting silicon nanowires. Precise control over the growth conditions allows for the synthesis of nanowires with desired dimensions and properties.

For instance, SiNWs can be grown by vapor deposition at a temperature of T=1,250-1,650° K or 975-1,375° C.). The SiNWs' growth may be conducted with the participation of catalytic particles, which represent a supersaturated solution of a crystallizable substance in liquid drops of Cu, Ni, Fe, Ti, Al, and Mg of a small volume.

In some of our work, the fusion of catalyst particles with the deposited Si was conducted at 1,373-1,673° K. The temperature of the growth process was chosen in the ranges of 1,250-1,650° K and 850-1,100° K and was higher than the eutectic for each selected Metal-Si system. The following temperatures were used for the growth of SiNWs for each catalyst metal: 1,643° K for Ti, 1,273° K for Mg, 1,073-1,273° K for Al, 1,173-1,273° K for C.u, 1,323-1,473° K for Ni, and 1,543° K for Fe. The concentration of Si in droplets composed of catalyst metals for SiNW growth at the growth temperatures was typically ~30% (atomic) for the Al—Si system, ~35% (atomic) for the Cu—Si system, ~57% (atomic) for the Mg—Si system, ~65% (atomic) for the Ni—Si system, ~67% (atomic) for the Fe—Si system, and ~90% (atomic) for the Ti—Si system.

The first catalyst dispersed inside the pores of the host may be produced by a procedure selected from physical vapor deposition, chemical vapor deposition, sputtering, plasma deposition, laser ablation, plasma spraying, ultrasonic spraying, printing, electrochemical deposition, electrode plating, electrodeless plating, chemical plating, solution deposition, thermal decomposition, or a combination thereof.

The first catalyst may be produced from a catalytic metal precursor comprising a salt or organo-metal molecule of a metal selected from Cu, Sn, Ga, Zn, Mg, Ni, Co, Mn, Fe, Ti, Al, Ag, Au, In, Pt, Pd, or a combination thereof. Preferably, the salt comprises a nitrate, acetate, sulfate, phosphate, hydroxide, or carboxylate of a metal selected from Cu, Sn, Ga, Zn, Mg, Ni, Co, Mn, Fe, Ti, Al, Ag, Au, In, Pt, Pd, or a combination thereof. Such a salt may be dissolved in a solvent (e.g., water) to obtain a solution, which is then impregnated into the pores of the host structure. By removing the solvent (e.g., heat-induced or vacuum-assisted vaporization) from the host structure, the salt gets dispersed on the pore walls. The salt may then be thermally reduced or decomposed into nano-scale metal particles or coating having a diameter or thickness from 0.5 nm to 100 nm (preferably smaller than 20 nm, more preferably smaller than 10 nm, and most preferably from 1 nm to 5 nm). These nano coating or particles serve as the first catalyst to initiate the Si nanowires.

In the method, the Si source in a powder form (to be reacted with a halogen), may be in physical contact with a second catalyst or the second catalyst is dispersed in said Si source powder of particles. The second catalyst preferably comprises a metal, a metal alloy, a metal oxide, a metal salt, a metal hydride, a metal-containing compound, or a combination thereof, wherein the metal is selected from a group of elements consisting of noble metal elements, alkaline and alkaline earth metal elements, transition metal elements, rare earth metal elements, low melting point metal elements, and combinations thereof.

The disclosed porous particulates (in a powder form) can be readily incorporated with an optional binder and optional conductive additive to form a thick anode (negative electrode) of high areal capacity, typically higher than 4.5 mAh/cm², more typically higher than 6 mAh/cm², further typically and desirably higher than 10 mAh/cm², still more typically and desirably higher than 20 mAh/cm², 30 mAh/cm², 50 mAh/cm², etc. These high areal capacities normally could not be achieved if one chooses to deposit pure Si directly on a current collector.

The porous graphene particles preferably comprise pore walls comprising graphene sheets selected from pristine graphene, graphene fluoride, graphene chloride, graphene bromide, graphene iodide, nitrogenated graphene, hydrogenated graphene, doped graphene, chemically functionalized graphene, graphene oxide, reduced graphene oxide, or a combination thereof. The production of these graphene materials is well-known in the art.

There is a broad array of porous graphene particles (also herein referred to as graphene balls) that can be included in the disclosed graphene composite structure. Some examples are schematically shown in FIGS. 3(A) and 3(B).

As schematically illustrated in FIG. 3(A), the graphene ball comprises self-bonded graphene sheets (e.g., graphene oxide sheets) in the pore walls that are (1) chemically linked/merged together (edge-to-edge and/or face-to-face) typically at a temperature from 100 to 1,500° C. for graphene oxide sheets and/or (2) re-organized into larger graphite crystals or domains (herein referred to as re-graphitization) along the pore walls at a high temperature (typically >2,100° C. and more typically >2,500° C.) during the presently disclosed heat treatment procedure.

The porous carbonaceous or graphitic particles preferably comprise particles of activated carbon, soft carbon (defined as a carbon material that is graphitizable), hard carbon (not graphitizable even at a temperature higher than 2,500° C.), activated natural graphite, activated artificial graphite, exfoliated graphite worms, expanded graphite flakes, meso-phase carbon, needle coke, or a combination thereof.

In some embodiments, the process further includes a procedure of prelithiating the multiple anode material particulates, wherein said anode material is prelithiated to contain an amount of lithium from 1% to 100% of a maximum lithium content contained in said anode active material.

The anode active material (e.g., Si coatings, nano particles, and/or nanowires) in the pores of porous host particles may be prelithiated before or after the anode fabrication, for the purpose of improving the first-cycle efficiency of a resulting lithium-ion cell. Prelithiation of anode active materials, such as Si, can be accomplished in several different ways that can be classified into 3 categories: physical methods, electrochemical methods, and chemical methods. The chemical methods are typically conducted by sourcing lithium atoms from active reactants or lithium metal. The active reactants can include organometallic compounds and lithium salts and the reactions can be effectuated ex-situ (in a chemical reactor before anode fabrication, or after anode fabrication but before cell assembly). One may also bring lithium metal in direct contact with particles of the desired anode active material in a dry condition or with the presence of a liquid electrolyte.

A physical process entails depositing a Li coating on a surface of an anode active material substrate (e.g., a layer of Si-containing particles), followed by promoting thermally induced diffusion of Li into the substrate (e.g., into the interior of a Si deposited on pore walls of host particles). A thin lithium layer can be deposited on the surface of an anode material substrate using a standard thin film process, such as thermal evaporation, electron beam evaporation, sputtering, and laser ablation. A vacuum is preferably used during the deposition process to avoid reactivity between the atomic lithium and molecules of lithium-reactive substances such as water, oxygen, and nitrogen. A vacuum of greater than 1 milli-Torr is desirable. When electron beam deposition is used a vacuum of 10⁻⁴ Torr is desired and a vacuum of 10⁻⁶ Torr is preferred to avoid interaction between the electron beam and any residual air molecules.

The evaporative deposition techniques involve the heating of a lithium metal to create a lithium vapor. The lithium metal can be heated by an electron beam or by resistive heating of the lithium metal. The lithium vapor deposits lithium onto a substrate composed of packed Si-containing particles. To promote the deposition of lithium metal the substrate can be cooled or maintained at a temperature lower than the temperature of the lithium vapor. A thickness monitor such as a quartz crystal type monitor can be placed near the substrate to monitor the thickness of the film being deposited. Alternatively, laser ablation and sputtering techniques can be used to promote thin lithium film growth on a substrate. For example, argon ions can be used in the sputtering process to bombard a solid lithium metal target. The bombarding knocks lithium off of the target and deposits it on the surface of a substrate. Laser ablation processes can be used to knock lithium off of a lithium target. The separated lithium atoms are then deposited onto the substrate. The lithium-coated layer of packed Si-containing particles (Si as an example of an anode active material) is then immersed into a liquid electrolyte containing a lithium salt dissolved in an organic solvent. Lithium atoms rapidly permeate into the bulk of Si (e.g., Si nanowires) to form prelithiated Si. Physical methods may also be conducted by simply mixing molten lithium metal with the anode particulates.

The anode active material preferably comprises silicon and the prelithiated particles comprise a prelithiated silicon, Li₄Si, Li_{4.4}Si, or LiₓSi, wherein numerical x is between 1 and 4.4.

The prelithiated anode active material particles may be subsequently subjected to a surface treatment that produces a surface-stabilizing coating to embrace the prelithiated particles, wherein this surface-stabilizing coating is an ion-conducting material layer, such as a polymer electrolyte, an ion-conducting elastomer, a layer of composite comprising lithium- or sodium-containing species that are chemically bonded to the prelithiated particles.

The protective layer of the instant invention typically exhibits a lithium ion or sodium ion conductivity from 2.5×10⁻⁵ S/cm to 5.5×10⁻³ S/cm, and more typically from 1.0×10⁻⁴ S/cm to 2.5×10⁻³ S/cm. The anode active material may be made into a thin film and then the Li- or Na-containing species are coated thereon and then peeled off to allow for ion conductivity measurement.

Several micro-encapsulation processes can be used to embrace/encapsulate particles of an anode active material (with or without prelithiation) with a protective layer. This preferably requires dissolution of a lithium salt, a sodium salt, multiple lithium salts, and/or multiple sodium salts in a solvent (including mixture of multiple solvents) to form a solution. This solution can then be used to encapsulate solid particles via several of the micro-encapsulation methods to be discussed in what follows. The same type of encapsulation processes may be used to encapsulate the disclosed porous conducting host particles containing an anode active material deposited therein, with or without prelithiation.

There are three broad categories of micro-encapsulation methods that can be implemented to produce encapsulated particles of an anode active material: physical methods, physico-chemical methods, and chemical methods. The physical methods include pan-coating, air-suspension coating, centrifugal extrusion, vibration nozzle, and spray-drying methods. The physico-chemical methods include ionotropic gelation and coacervation-phase separation methods. The chemical methods include interfacial polycondensation or other surface reactions. Several methods are discussed below as examples.

Pan-coating method: The pan coating process involves tumbling the active material particles in a pan or a similar device while the encapsulating material (e.g. highly concentrated solution of Li/Na salts in a solvent) is applied slowly until a desired encapsulating shell thickness is attained.

Air-suspension coating method: In the air suspension coating process, the solid particles (core material) are dispersed into the supporting air stream in an encapsulating chamber. A controlled stream of a salt-solvent solution (with an optional polymer) is concurrently introduced into this chamber, allowing the solution to hit and coat the suspended particles. These suspended particles are encapsulated (fully coated) with the salts while the volatile solvent is removed, leaving a very thin layer of Li and/or Na salts on surfaces of these particles. This process may be repeated several times until the required parameters, such as full-coating thickness (i.e. encapsulating shell or wall thickness), are achieved. The air stream which supports the particles also helps to dry them, and the rate of drying is directly proportional to the temperature of the air stream, which can be adjusted for optimized shell thickness.

In a preferred mode, the particles in the encapsulating zone portion may be subjected to re-circulation for repeated coating. Preferably, the encapsulating chamber is arranged such that the particles pass upwards through the encapsulating zone, then are dispersed into slower moving air and sink back to the base of the encapsulating chamber, enabling repeated passes of the particles through the encapsulating zone until the desired encapsulating shell thickness is achieved.

Centrifugal extrusion: Anode active materials may be encapsulated using a rotating extrusion head containing concentric nozzles. In this process, a stream of core fluid (slurry containing particles of an anode active material dispersed in a solvent) is surrounded by a sheath of shell solution or melt. As the device rotates and the stream moves through the air it breaks, due to Rayleigh instability, into droplets of core, each coated with the shell solution. While the droplets are in flight, the molten shell may be hardened or the solvent may be evaporated from the shell solution. If needed, the capsules can be hardened after formation by catching them in a hardening bath. Since the drops are formed by the breakup of a liquid stream, the process is only suitable for liquid or slurry. A high production rate can be achieved. Up to 22.5 kg of microcapsules can be produced per nozzle per hour and extrusion heads containing 16 nozzles are readily available.

Vibrational nozzle method: Core-shell encapsulation of an anode active material can be conducted using a laminar flow through a nozzle and vibration of the nozzle or the liquid. The vibration has to be done in resonance with the Rayleigh instability, leading to very uniform droplets. The liquid can include any liquids with limited viscosities (1-50,000 mPa·s): emulsions, suspensions or slurry containing the anode active material. The solidification can be done according to the used gelation system with an internal gelation (e.g. sol-gel processing, melt) or an external (additional binder system, e.g. in a slurry).

Spray-drying: Spray drying may be used to encapsulate particles of an active material when the active material is dissolved or suspended in a melt or polymer solution. In spray drying, the liquid feed (solution or suspension) is atomized to form droplets which, upon contacts with hot gas, allow solvent to get vaporized and thin polymer shell to fully embrace the solid particles of the active material.

It may be noted that the anode active material (e.g., prelithiated or non-lithiated particulates) may be coated with a carbonizable coating material (e.g., phenolic resin, poly(furfuryl alcohol), coal tar pitch, or petroleum pitch). The coating can then be carbonized to produce an amorphous carbon or polymeric carbon coating on the surface of these particulates. Such a conductive surface coating can help maintain a network of electron-conducting paths during repeated charge/discharge cycles and prevent undesirable chemical reactions between Si and electrolyte from happening. Hence, the presently invented method may further comprise a step of coating a surface of the particulates with a thin layer of carbon having a thickness less than 1 μm. The thin layer of carbon preferably has a thickness less than 100 nm. Such a thin layer of carbon may be obtained from pyrolization of a polymer, pitch, or organic precursor or obtained by chemical vapor deposition, physical vapor deposition, sputtering, etc.

Alternatively, the particulates containing an anode active material therein may be coated with a layer of electron-conducting polymer or ion-conducting polymer. Such coating processes are well-known in the art.

The surface-stabilized or surface-stabilized and prelithiated particles of an anode active material (with or without a coating of carbon, graphene, electron-conducting polymer, or ion-conducting polymer) may be further encapsulated by a thin layer of a high-elasticity polymer (e.g. an elastomer) having a fully recoverable tensile strain of from 5% to 700% and a thickness preferably from 0.5 nm to 2 μm (preferably from 1 nm to 100 nm). The elastomer preferably has a lithium ion conductivity from 10⁻⁷ S/cm to 5×10⁻² S/cm at room temperature (preferably and typically no less than 10⁻⁶ S/cm, further preferably no less than 10⁻⁵ S/cm, more preferably no less than 10⁻⁴ S/cm, and most preferably no less than 10⁻³ S/cm).

In others, the elastomeric material is an elastomer matrix composite containing from 0.1% to 50% by weight (preferably from 1% to 35% by weight) of a lithium ion-conducting additive dispersed in an elastomer matrix material.

In some embodiments, the elastomeric material contains a material selected from natural polyisoprene (e.g. cis-1,4-polyisoprene natural rubber (NR) and trans-1,4-polyisoprene gutta-percha), synthetic polyisoprene (IR for isoprene rubber), polybutadiene (BR for butadiene rubber), chloroprene rubber (CR), polychloroprene (e.g. Neoprene, Baypren etc.), butyl rubber (copolymer of isobutylene and isoprene, IIR), including halogenated butyl rubbers (chloro butyl rubber (CIIR) and bromo butyl rubber (BIIR), styrene-butadiene rubber (copolymer of styrene and butadiene, SBR), nitrile rubber (copolymer of butadiene and acrylonitrile, NBR), EPM (ethylene propylene rubber, a copolymer of ethylene and propylene), EPDM rubber (ethylene propylene diene rubber, a terpolymer of ethylene, propylene and a diene-component), epichlorohydrin rubber (ECO), polyacrylic rubber (ACM, ABR), silicone rubber (SI, Q, VMQ), fluorosilicone rubber (FVMQ), fluoroelastomers (FKM, and FEPM; such as Viton, Tecnoflon, Fluorel, Aflas and Dai-El), perfluoroelastomers (FFKM: Tecnoflon PFR, Kalrez, Chemraz, Perlast), polyether block amides (PEBA), chlorosulfonated polyethylene (CSM; e.g. Hypalon), and ethylene-vinyl acetate (EVA), thermoplastic elastomers (TPE), protein resilin, protein elastin, ethylene oxide-epichlorohydrin copolymer, polyurethane, urethane-urea copolymer, and combinations thereof.

The urethane-urea copolymer film usually includes two types of domains, soft domains and hard ones. Entangled linear backbone chains including poly(tetramethylene ether) glycol (PTMEG) units constitute the soft domains, while repeated methylene diphenyl diisocyanate (MDI) and ethylene diamine (EDA) units constitute the hard domains. The lithium ion-conducting additive can be incorporated in the soft domains or other more amorphous zones.

In some embodiments, the elastomeric material is an elastomer matrix composite containing a lithium ion-conducting additive dispersed in an elastomer matrix material, wherein said lithium ion-conducting additive is selected from Li₂CO₃, Li₂O, Li₂C₂O₄, LiOH, LiX, ROCO₂Li, HCOLi, ROLi, (ROCO₂Li)₂, (CH₂OCO₂Li)₂, Li₂S, LiₓSO_{y}, or a combination thereof, wherein X=F, Cl, I, or Br, R=a hydrocarbon group, x=0-1, y=1-4.

In some embodiments, the elastomeric material is an elastomer matrix composite containing a lithium ion-conducting additive dispersed in an elastomer matrix material, wherein said lithium ion-conducting additive contains a lithium salt selected from lithium perchlorate, LiClO₄, lithium hexafluorophosphate, LiPF₆, lithium borofluoride, LiBF₄, lithium hexafluoroarsenide, LiAsF₆, lithium trifluoro-metasulfonate, LiCF₃SO₃, bis-trifluoromethyl sulfonylimide lithium, LiN(CF₃SO₂)₂, lithium bis(oxalato) borate, LiBOB, lithium oxalyldifluoroborate, LiBF₂C₂O₄, lithium oxalyldifluoroborate, LiBF₂C₂O₄, lithium nitrate, LiNO₃, Li-Fluoroalkyl-Phosphates, LiPF₃ (CF₂CF₃)₃, lithium bisperfluoro-ethysulfonylimide, LiBETI, lithium bis(trifluoromethanesulphonyl)imide, lithium bis(fluorosulphonyl)imide, lithium trifluoromethanesulfonimide, LiTFSI, an ionic liquid-based lithium salt, or a combination thereof.

The elastomeric material may contain a mixture or blend of an elastomer and an electron-conducting polymer selected from polyaniline, polypyrrole, polythiophene, polyfuran, a bi-cyclic polymer, derivatives thereof (e.g. sulfonated versions), or a combination thereof.

In some embodiments, the elastomeric material contains a mixture or blend of an elastomer and a lithium ion-conducting polymer selected from poly(ethylene oxide) (PEO), Polypropylene oxide (PPO), poly(acrylonitrile) (PAN), poly(methyl methacrylate) (PMMA), poly(vinylidene fluoride) (PVdF), Poly bis-methoxy ethoxyethoxide-phosphazenex, Polyvinyl chloride, Polydimethylsiloxane, poly(vinylidene fluoride)-hexafluoropropylene (PVDF-HFP), a derivative thereof (e.g. sulfonated versions), or a combination thereof.

In the preparation of an anode electrode, acetylene black (AB), carbon black (CB), or ultra-fine graphite particles may be used as a conductive additive. Conductive additives may comprise an electrically conductive material selected from the group consisting of electro-spun nano fibers, carbonized electro-spun nano fibers, vapor-grown carbon or graphite nano fibers, carbon or graphite whiskers, carbon nano-tubes, nano-scaled graphene platelets, metal nano wires, metal-coated nano wires, carbon-coated nano wires, metal-coated nano fibers, carbon-coated nano fibers, and combinations thereof. A binder material may be chosen from polytetrafluoroethylene (PTFE), polyvinylidene fluoride (PVDF), ethylene-propylene-diene copolymer (EPDM), or styrene-butadiene rubber (SBR), for example. Conductive materials such as electronically conductive polymers, meso-phase pitch, coal tar pitch, and petroleum pitch may also be used as a binder. A typical mixing ratio of these ingredients is 80 to 85% by weight for the anode active material, 5 to 15% by weight for the conductive additive, and 5 to 10% by weight for the binder. The current collector may be selected from aluminum foil, stainless steel foil, and nickel foil. There is no particularly significant restriction on the type of current collector, provided the material is a good electrical conductor and relatively corrosion resistant. The separator may be selected from a polymeric nonwoven fabric, porous polyethylene film, porous polypropylene film, or porous PTFE film.

The electrode fabrication may comprise combining multiple fine particles of prelithiated anode active material with a conductive additive and/or a binder material, plus a desired amount of another type of anode active materials selected from particles of graphite, hard carbon, soft carbon, meso-carbon micro-bead, surface-modified graphite, carbon-coated graphite, or a combination thereof.

Hence, a lithium ion battery may contain an anode that comprises at least two types of anode active material wherein at least one type of active material is prelithiated (e.g., Si and Sn) and at least one type of active material is not prelithiated (e.g., carbonaceous material, such as graphite, hard carbon, soft carbon, surface-modified graphite, chemically modified graphite, or meso-carbon micro-beads, MCMBs). Prelithiated carbonaceous anode materials are unstable in regular room air. The present invention enable the battery to contain an anode that comprises at least a non-carbon active material possessing an ultra-high lithium absorbing capacity (e.g., Si that exhibits a specific capacity up to 4,200 mAh/g). The battery comprises an anode that contains an excess amount of lithium (disposed inside a non-carbon anode active material, not on its surface) to compensate for the formation of SEI layers, in addition to providing enough lithium to intercalate into (or form a compound with) a cathode active material.

The present invention allows the excess amount of lithium to be stored in high-capacity anode active materials (there is no need to make use of the full capacity of Si, for instance). The capacity limitation is on the cathode side, rather than the anode side. The present approach obviates the need for the cathode to supply the needed lithium, thereby further reducing the needed initial weight of the cathode or increasing the cathode weight that can be incorporated in a cell. This strategy can increase the overall capacity of a lithium ion battery by another 10%-20%.

There is no limitation on the types of cathode materials that can pair up with the presently invented anode materials. The positive electrode active material may be selected from a wide variety of oxides, such as lithium-containing nickel oxide, lithium-containing cobalt oxide, lithium-containing nickel-cobalt oxide, lithium-containing vanadium oxide, lithium iron phosphate, lithium manganese phosphate, lithium manganese-iron phosphate, and other lithium metal (or mixed metals) phosphate. Positive electrode active material may also be selected from chalcogen compounds, such as titanium disulfate or molybdenum disulfate. More preferred are lithium cobalt oxide (e.g., LiₓCoO₂ where 0.8≤x≤1), lithium nickel oxide (e.g., LiNiO₂), lithium manganese oxide (e.g., LiMn₂O₄ and LiMnO₂), lithium iron phosphate, lithium manganese-iron phosphate, lithium vanadium phosphate because these oxides provide a relatively high cell voltage and relatively good cycling stability.

Lithium cobalt oxide (LiCoO₂) is one of the most important cathode materials used in lithium-ion secondary batteries. LiCoO₂ and other similar lithium transition metal oxides, such as lithium manganese oxide, lithium nickel oxide, and lithium vanadium oxide, can be prepared by various methods using different lithium and transition metal sources. In general, bulk transition metal oxides are prepared by solid-state reactions, which involve repeated heat processes at high temperatures. Such processes generally afford the thermodynamically more stable phases and in general, microcrystalline materials are obtained. Lower temperatures and mild processing conditions may be used for several methods, such as co-precipitation, sol-gel process with/without template, synthesis by precursor, ion-exchange reaction and hydrothermal. These methods also result in particles with better control of morphology and smaller size. Other methods include flame spray pyrolysis, dehydro-freezing evaporation, supercritical dehydration, supersonic hydrothermal synthesis, and ultrasonic processing.

As an example, a process for producing lithium-cobalt oxide my include (a) mixing cobalt oxide having an average particle size of not more than 0.1 μm, with a lithium compound; and (b) calcining the obtained mixture at a temperature of 500 to 850° C. As compared to the conventional processes that begin with larger cobalt oxide particles (e.g., diameter>10 μm), such a process is advantageous in that lithium-cobalt oxide particles (1) can be produced with a short calcination time, (2) have a narrow particle size distribution, and (3) have a uniform small particle size.

The flame-spray pyrolysis method may include the steps of: (a) spraying minute droplets containing a solution of dissolved lithium salt and cobalt salt at room temperature; (b) atomizing the minute droplets through rapid expansion into a high temperature environment generated by combusting oxygen and hydrogen; (c) decomposing and oxidizing the atomized minute droplets thermally at high temperature to produce nano-sized oxides in gaseous phase; and (d) collecting the produced nano-sized composite oxides particles.

Lithium iron phosphate LiFePO₄ is a promising candidate of cathode material for lithium-ion batteries. The advantages of LiFePO₄ as a cathode active material includes a high theoretical capacity (170 mAh/g), environmental benignity, low resource cost, good cycling stability, high temperature capability, and prospect for a safer cell compared with LiCoO₂. A major drawback with this material is that it has very low electronic conductivity, on the order of 10⁻⁹ S/cm². This renders it difficult to prepare cathodes capable of operating at high rates. In addition, poor solid-phase transport means that the utilization of the active material is a strong function of the particle size. This major problem may be overcome by using a nano-scaled powder (to reduce the Li ion diffusion path and electron transport path distance) and doping the powder with a transition metal. Lithium iron phosphate (LiFePO₄) nano particles may be prepared by ball milling of conventional micron-sized particles, which may be prepared by a solid state reaction using LiOH·H₂O, (CH₃COO)₂Fe, and NH₄H₂PO₄ as raw materials. Additionally, Li_{1.3}Al_{0.3}Ti_{1.7}(PO₄)₃ materials, as an example of lithium mixed-metal phosphate, may be successfully prepared by the solution deposition using lithium acetate, aluminum nitrate, ammonium dihydrogen phosphate and titanium butoxide as starting materials. The resulting material may be ball-milled to sub-micron or nanometer scales. This is but one example of a host of complex metal phosphate-based cathode materials.

A wide range of electrolytes can be incorporated into the lithium cells. Most preferred are non-aqueous and polymer gel electrolytes although other types can be used. The non-aqueous electrolyte to be employed herein may be produced by dissolving an electrolytic salt in a non-aqueous solvent. Any known non-aqueous solvent which has been employed as a solvent for a lithium secondary battery can be employed. A non-aqueous solvent mainly consisting of a mixed solvent comprising ethylene carbonate (EC) and at least one kind of non-aqueous solvent whose melting point is lower than that of aforementioned ethylene carbonate (hereinafter referred to as a second solvent) may be preferably employed. This non-aqueous solvent is advantageous in that it is (a) stable against a negative electrode containing a carbonaceous material well developed in graphite structure; (b) effective in suppressing the reductive or oxidative decomposition of electrolyte; and (c) high in conductivity. A non-aqueous electrolyte solely composed of ethylene carbonate (EC) or fluorinated EC is advantageous in that it is relatively stable against decomposition through a reduction by a graphitized carbonaceous material. However, the melting point of EC is relatively high, 39 to 40° C., and the viscosity thereof is relatively high, so that the conductivity thereof is low, thus making EC alone unsuited for use as a secondary battery electrolyte to be operated at room temperature or lower. The second solvent to be used in a mixture with EC functions to make the viscosity of the solvent mixture lower than that of EC alone, thereby promoting the ion conductivity of the mixed solvent. Furthermore, when the second solvent having a donor number of 18 or less (the donor number of ethylene carbonate is 16.4) is employed, the aforementioned ethylene carbonate can be easily and selectively solvated with lithium ion, so that the reduction reaction of the second solvent with the carbonaceous material well developed in graphitization is assumed to be suppressed. Further, when the donor number of the second solvent is controlled to not more than 18, the oxidative decomposition potential to the lithium electrode can be easily increased to 4 V or more, so that it is possible to manufacture a lithium secondary battery of high voltage.

Preferable second solvents are dimethyl carbonate (DMC), methylethyl carbonate (MEC), diethyl carbonate (DEC), ethyl propionate, methyl propionate, propylene carbonate (PC), .gamma.-butyrolactone (.gamma.-BL), acetonitrile (AN), ethyl acetate (EA), propyl formate (PF), methyl formate (MF), toluene, xylene and methyl acetate (MA). These second solvents may be employed singly or in a combination of two or more. More desirably, this second solvent should be selected from those having a donor number of 16.5 or less. The viscosity of this second solvent should preferably be 28 cps or less at 25° C.

The mixing ratio of the aforementioned ethylene carbonate in the mixed solvent should preferably be 10 to 80% by volume. If the mixing ratio of the ethylene carbonate falls outside this range, the conductivity of the solvent may be lowered or the solvent tends to be more easily decomposed, thereby deteriorating the charge/discharge efficiency. More preferable mixing ratio of the ethylene carbonate is 20 to 75% by volume. When the mixing ratio of ethylene carbonate in a non-aqueous solvent is increased to 20% by volume or more, the solvating effect of ethylene carbonate to lithium ions will be facilitated and the solvent decomposition-inhibiting effect thereof can be improved.

Examples of preferred mixed solvent are a composition comprising EC and MEC; comprising EC, PC and MEC; comprising EC, MEC and DEC; comprising EC, MEC and DMC; and comprising EC, MEC, PC and DEC; with the volume ratio of MEC being controlled within the range of 30 to 80%. By selecting the volume ratio of MEC from the range of 30 to 80%, more preferably 40 to 70%, the conductivity of the solvent can be improved. With the purpose of suppressing the decomposition reaction of the solvent, an electrolyte having carbon dioxide dissolved therein may be employed, thereby effectively improving both the capacity and cycle life of the battery.

The electrolytic salts to be incorporated into a non-aqueous electrolyte may be selected from a lithium salt such as lithium perchlorate (LiClO₄), lithium hexafluorophosphate (LiPF₆), lithium borofluoride (LiBF₄), lithium hexafluoroarsenide (LiAsF₆), lithium trifluoro-metasulfonate (LiCF₃SO₃) and bis-trifluoromethyl sulfonylimide lithium [LiN(CF₃SO₂)₂]. Among them, LiPF₆, LiBF₄ and LiN(CF₃SO₂)₂ are preferred. The content of aforementioned electrolytic salts in the non-aqueous solvent is preferably from 0.5 to 2.0 mol/l.

### Example 1A: Production of Porous Graphene Particles (Graphene Balls) and Si Nanowire Deposition in the Pores of Graphene Balls (with or without the Use of a Particle-Moving Device)

In a representative procedure, 1 kg of polypropylene (PP) pellets, 50 grams of flake graphite, 50 mesh (average particle size 0.18 mm; Asbury Carbons, Asbury NJ) and 250 grams of magnetic steel balls were placed in a high-energy ball mill container. The ball mill was operated at 300 rpm for 2 hours. The container lid was removed and stainless steel balls were removed via a magnet. The polymer carrier material was found to be coated with a dark graphene layer. Carrier material was placed over a 50 mesh sieve and a small amount of unprocessed flake graphite was removed.

A sample of the coated carrier material was then submitted to air flow suspension in a heated chamber, wherein the graphene-coated PP particles were heat-treated at 350° C. and then at 600° C. for 2 hours to produce individual (isolated/separated) porous graphene balls.

In a separate experiment, the same batch of PP pellets and flake graphite particles (without the impacting steel balls) were placed in the same high-energy ball mill container and the ball mill was operated under the same conditions for the same period of time. The results were compared with those obtained from impacting ball-assisted operation. The graphene sheets isolated from PP particles, upon PP dissolution, are mostly single-layer graphene. The graphene balls produced from this process typically have a higher level of porosity (lower physical density).

Porous graphene balls were impregnated with Ni nano particles (as the first catalyst to facilitate the initiation and growth of Si nanowires, SiNWs) by immersing the graphene balls in a nickel salt/water solution. The nickel acetate (Ni(CH₃COO)₂) is soluble in water. It is an ionic compound which readily dissociates into its ions in water. Upon removal of water, nickel acetate was dispersed as a thin film (23 nm thick) on pore walls of the graphene balls. The thermal reduction of nickel acetate (Ni(CH₃COO)₂) to metallic nickel (Ni) involves heating the nickel acetate compound to a high temperature (300° C. for 1 hour and then 500° C. for 2 hours, the latter in a hydrogen reducing atmosphere), which causes the acetate groups to decompose, leaving behind elemental nickel nano particles having a diameter of approximately 5-11 nm.

After the porous graphene balls were prepared, they were positioned in the decomposition/deposition zone of the reactor (FIG. 4(D)) equipped with a fluidized bed device. Solid silicon halide (SiI₄) powder was placed in the vaporization zone, which was heated at 600° C. to generate silicon iodide (SiI₄) vapor. The SiI₄ vapor was directed to flow into the decomposition/deposition zone to impinge upon the porous graphene ball pores (pre-set at 1,175° C.), and permeate into pores of these open-cell graphene balls (preloaded with Ni nano particles).

Two separate experiments were conducted: first one with the fluidized bed device turned on, allowing the fluidizing gas to flow into the chamber zone where the porous graphene particles were located and the second one with the fluidized bed device turned off. In both experiments, Si nanowires were found to grow to approximately 24-31 nm in diameter, presumably at a temperature close to 1,150° C. (the eutectic point of Si—Ni alloy). The graphene balls were impregnated with Si nanowires, but still maintaining a desired porosity level (pore-to-Si volume ratio varying from 1.1 to 3.1).

Most importantly, with the same length of Si deposition time, the first one (with the particle-moving device being activated) led to more uniform amounts of SiNWs deposited among different porous host particles (Si weight fractions ranging from 73.5% to 78.1% based on the average composite particle weight). In contrast, the one without the assistance of a particle-moving device led to a much broader range of Si weight fraction from 64.5% to 80.6%. A narrower range of Si contents is more desirable in terms of better product quality control and more consistent lithium ion storage capacities.

### Example 1B: Production of Porous Graphene Balls from Flake Graphite and Deposition of Si Coatings and Nano Particles in the Pores of Graphene Balls (with or without the Use of a Particle-Moving Device)

The same procedure as in Example 1A was followed with the exception that no Ni catalyst was preloaded to the graphene balls. In addition, the decomposition chamber of set at a temperature of 1,200° C. and the graphene balls at approximately 1,000° C. The Si coatings and some nano particles were deposited on pore walls. The Si coatings and Si nano particles have a thickness or diameter typically from 7 nm to 45 nm. Again, two separate experiments were conducted: first one with the fluidized bed device turned on, allowing the fluidizing gas to flow into the chamber zone where the porous graphene particles were located and the second one with the fluidized bed device turned off.

Again, with the same length of Si deposition time, the first one (with the particle-moving device being activated) led to more uniform amounts of Si coatings deposited among different porous host particles (Si weight fractions ranging from 73.8% to 78.6% based on the average composite particle weight). In contrast, the one without the assistance of a particle-moving device led to a range of Si weight fraction from 64.8% to 81.4%.

### Example 2A: Production of Si Nanowire-Inhabited Graphene Foam Structure-Derived Powder Particles (with or without the Use of a Particle-Moving Device)

Powders of graphene foam particles, produced by hydrothermal reduction of graphene oxide, were supplied from Angstron Materials, Inc. (Dayton, Ohio).

The pore walls of porous graphene foam particles were then deposited with metallic tin (Sn, as the first catalyst to promote the formation of SiNWs) from a tin salt solution. Solution deposition of tin metal refers to a technique where a thin tin metal film is deposited onto a substrate (here pore wall graphene surface) by applying a liquid solution containing a soluble tin compound, typically a tin salt like tin nitrate (Sn(NO₃)₂), which then undergoes a chemical reaction to precipitate the metallic tin onto the desired surface through an electrochemical process. In electrodeposition, an electric current is applied to drive the reduction of tin ions to metallic tin at the cathode. Factors like the concentration of tin ions in the solution, the applied voltage, the pH level, and the deposition time can influence the thickness and quality of the deposited tin film. Typically, the tin film thickness in our studies was in the range of 31-62 nm.

Porous graphene foam particles, containing tin catalyst therein, were then placed in the decomposition chamber of an internal quartz tube. This apparatus was similar to that schematically illustrated in FIG. 4(D), but the particle-moving device was different. In this example, this internal quartz tube (protected around by a heated stainless steel tubing) was connected to a small electric motor that rotated the inner tube in one direction for 90-270 degrees and then reversed the direction for the same 90-270 degrees. These rotations were repeated continually while Si atoms were injected into the deposition zone. Silicon halide (SiI₄) powder was placed in the vaporization zone (also serving partially as a silicon halide decomposition zone) set at a temperature of 680° C. The decomposition/deposition zone was set at 450° C. to produce SiNW-inhabited graphene balls.

The growth species, here silicon atoms, originate after the dissociation of SiI₄ gas that passes over the decomposition zone. These silicon containing species interact with Sn nanoparticles in the pores of the host and form an alloy in the liquid phase near the eutectic temperature. With continuous supply of silicon atoms, the liquid alloy reaches supersaturation resulting in precipitation of Si atoms at the growth front. Further growth takes place essentially in one dimension due to rapid diffusion of silicon through the catalyst nanoparticles following the VLS mechanism which is confirmed by the presence of the metallic Sn tip on the free end of nanowire as seen in SEM images. Due to the high surface-to-volume ratio of the Sn nanoparticles, they offer high catalytic activity to the incident silicon species, facilitating initiation and growth of Si nanowires.

Again, moving the graphene foam particles around while being deposited led to significantly more uniform Si deposition as reflected by a narrower range of Si amounts being included in the pores of the porous particles.

### Example 2B: Production of Graphene Foam Structures Containing Si Nano-Coatings/Particles

The same procedure as in Example 2A was followed with the exception that no Sn catalyst was preloaded to the graphene balls. Si coatings and some nano particles were deposited on pore walls. The Si coatings and Si nano particles have a thickness or diameter typically from 6 nm to 35 nm. Again, moving the graphene foam particles around while being deposited led to significantly more uniform Si deposition as reflected by a narrower range of Si amounts being included in the pores of the porous particles: 78.2-83.3% vs. 70.6-85.1%.

### Example 3: Production of Si Nano-Coating in the Pores of Metal Foam Particles

Nickel foam particles were produced by electroplating nickel onto a non-conductive foam precursor, then removing the precursor by a heat treatment. First, commercially available polyurethane (PU) foam was used as a non-conductive foam precursor, which was cut and milled into mm-sized particles. The PU foam particles were treated with a colloidal graphene oxide dispersion, followed by water removal. The conductive material-treated PU particles were then deposit with nickel using an electroplating procedure. The particles were then treated at high temperatures (>460° C.) to remove PU, forming highly porous Ni foam particles. These Ni foam particles were subjected to the same Si deposition treatment as in Example 2B. Uniform Si coatings were deposited into the pores of the Ni foam particles.

### Example 4: Production of Activated Carbon by Chemical Activation of MCMBs by ZnCl₂, Followed by Deposition of SiNWs in the Pores

We used two different amounts of starting material (400 g and 100 g). Other than this difference in starting amounts, all other variables were the same in the following activation procedures. The particles were impregnated with zinc chloride (ZnCl₂) at 1:1 wt. ratio and were kept at 80° C. for 14 h. Heat treatments were then carried out under constant nitrogen flow (5 l/h). The heat treatment temperature was raised at 4° C./min up to 500° C., which was maintained for 3 h. The samples were then washed to remove excess reagent and dried at 110° C. for about 3 h. The resulting samples were labeled as CA (chemically activated only). Part of these samples was then also submitted to physical activation. Temperature was raised to 900° C. at a rate of 25° C./min, under nitrogen flow. At 900° C., the samples were then contacted with steam (0.8 kg/h) for 30 min. These samples were then labeled as CAPA (both chemically and physically activated). It was observed that combined physical and chemical activation treatments led to a higher porosity level and slightly higher pore sizes that are more readily accessible to liquid electrolyte.

The porous activated graphite particulates were then impregnated with Ni nano particles by following the same procedure described in Example 1A.

The Ni catalyst-containing porous activated graphite particulates were then placed in the evaporation chamber (also a decomposition/deposition chamber, as schematically illustrated in FIGS. 4(E) and 4(F)) of a quartz tube, which was subjected to a rotational motion treatment (rather than fluidizing gas). The SiCl₄-impregnated porous activated graphite particulates were heated to a temperature of initially at 600° C., but gradually raised to 1,300° C. to facilitate fast decomposition of SiCl₄ vapor into Si and Cl species. The Si got to deposit into pores of the porous host particles and combine with Ni nano particles therein to produce SiNW-inhabited graphene balls. Again, moving the graphene foam particles around while being deposited led to significantly more uniform Si deposition as reflected by a narrower range of Si amounts being included in the pores of the porous particles: 68.8-74.6% vs. 63.5-75.1%.

### Example 5: Production of Activated Carbon by Chemical Activation of MCMBs by ZnCl₂, Followed by Deposition of Si Coatings/Particles in the Pores

The same procedure as in Example 4 was followed with the exception that no Ni catalyst was preloaded to the graphene balls. Si coatings and some nano particles were deposited on pore walls inside the particle pores. The Si coatings and Si nano particles have a thickness or diameter typically from 4.5 nm to 23 nm.

### Example 6: Chemical Activation of MCMBs by KOH, NaOH, and their Mixtures and Deposition of Si Nanowires in the Pores, Followed by Pre-Lithiation

In this example, several MCMB samples were separately mixed with KOH, NaOH, and their mixtures (30/70, 50/50, and 70/30 weight ratios) to obtain reactant blends. The blends were then heated to a desired temperature (in the range of 700-950° C.) and maintained at this temperature for 0.5-12 hours to produce various activated MCMB samples. The resulting structures vary with the previous heat treatment history of MCMBs, activation temperature, and activation time.

The porous MCMB particles were impregnated with Cu nano particles using electrodeposition. For the formation of Si nanowires in the Cu-inhabited pores, SiBr₄-impregnated porous MCMB particles were used as a host and were placed in the decomposition chamber (also serving as a Si deposition zone as schematically illustrated in FIGS. 4(E) and (F)) of a quartz tube, assisted with fluidizing gas flow. The reaction chamber (initially a combined evaporator/decomposer zone) had a temperature of 1,350° C., but the temperature was reduced to 850° C. to produce SiNW-infiltrated graphene balls.

Subsequently, chemical lithiation of the SiNWs was conducted by using 1 M lithium-biphenyl (Li-Bp)/tetrahydrofuran (THF) solution as the prelithiation reagent. Biphenyl (Bp) was chosen because of its unique chemical/electrochemical behavior in different solvents. In ether solvents (e.g., dimethoxyethane (DME) and THF), it can react with lithium metal and form a strong reducing reagent of Li-Bp. Moreover, the resulting Li-Bp solution is relatively stable toward air and moisture, which is critical to the prelithiation in ambient air. Prelithiation was conducted by simply immersing the SiNW-containing porous MCMB particles in the prelithiation reagent at room temperature for 10-100 minutes. The prelithiated Si-containing carbon particles were subsequently immersed in a liquid polymer solution including of PVDF-HFP dissolved in NMP and then retreated from the liquid solution and dried in a vacuum oven at 60° C. overnight to obtain surface-protected prelithiated anode particulates.

The electrodes were made of these porous, prelithiated particles, mixed with 5 wt % Super-P® and 7 wt % polytetrafluoroethylene (PTFE) binder. The procedure of slurry coating on Cu foil was conducted to produce electrodes having a thickness from 65 μm to 330 μm.

1. An apparatus for production of a solid powder mass of multiple porous particulates having pores containing silicon coatings, particles, and/or nanowires (SiNW) therein for use as an anode active material of a lithium-ion or sodium-ion battery, said apparatus comprising:
(A) a vaporization chamber or zone equipped with a heating device for vaporizing a silicon halide source to generate a silicon halide vapor or keeping a silicon halide vapor above its boiling point;
(B) a thermal decomposition chamber or zone equipped with a heating device for thermally decomposing the silicon halide vapor into Si atoms and halogen;
(C) a deposition chamber or zone, for receiving Si atoms and for holding multiple porous particles, and a heating device for heating said deposition chamber or zone and the multiple porous particles disposed therein to facilitate deposition of Si atoms in the pores of the multiple porous particles; and
(D) a particle-moving device for mobilizing said multiple porous particles to move around in the deposition chamber or zone to facilitate uniform infiltration and deposition of said Si atoms in pores of said porous particles to form silicon coatings, particles, and/or nanowires (SiNW) therein.

2. The apparatus of claim 1, wherein the vaporization chamber or zone and the thermal decomposition chamber or zone are adjacent to each other, contiguous to each other, or integrated into one chamber or zone.

3. The apparatus of claim 1, wherein the heating devices are equipped to heat or maintain the silicon halide above its boiling point, wherein the silicon halide is selected from SiF₄, SiCl₄, SiI₄, SiI₂, SiBr₄, SiXₐZ_{b}, or a combination thereof, wherein X and Z are each a halogen element, selected from F, Cl, Br, or I, and a=1-3, b=1-3, and a+b=4.

4. The apparatus of claim 1, further comprising a source of silicon halide vapor, disposed outside of the vaporization chamber and decomposition chamber, for delivering the silicon halide vapor into the vaporization chamber or zone vapor and/or the thermal decomposition chamber or zone.

5. The apparatus of claim 4, wherein said silicon halide vapor source and a carrier gas source deliver said silicon halide vapor and the carrier gas into the vaporization chamber or zone vapor and/or the thermal decomposition chamber or zone.

6. The apparatus of claim 1, wherein the vaporization chamber, decomposition chamber, and deposition chamber are substantially merged into one chamber.

7. The apparatus of claim 1, further comprising a holder in the vaporization chamber for holding a desired amount of silicon halide liquid or solid state, wherein the holder receives heat from a heating device.

8. The apparatus of claim 1, further comprising a reaction zone, for holding a desired amount of Si source, and a conduit for introducing a stream of halogen gas into said reaction zone wherein the halogen gas chemically reacts with the Si source at a reaction temperature to produce a silicon halide that is vaporized to form silicon halide vapor, wherein the Si source comprises Si or a Si-rich compound containing no less than 50% by weight of Si.

9. The apparatus of claim 1, wherein said particle-moving device is selected from a rotational furnace, rotational tube, fluidized bed apparatus, pneumatic conveyor, screw feeder, vibratory feeder, gravity chute, belt conveyor, bucket elevator, dipleg, cyclone, turbulent gas jet, spouted bed, packed bed reactor, or a combination thereof.

10. The apparatus of claim 1, further comprising a gas exhaust port and halogen gas collection device for exhausting and collecting the halogen gas, a byproduct of thermal decomposition.

11. The apparatus of claim 8, further comprising (i) a gas exhaust port and halogen gas collection device for exhausting and collecting the halogen gas, a byproduct of thermal decomposition; and (ii) a halogen delivery device for transporting the collected halogen gas into the reaction zone for reuse.
